(19) United States
(12) Patent Application Publication
(10) Pub. No.: US 2026/0239833 A1
(43) Pub. Date: Aug. 13, 2026

(54) DISPLAY DEVICE AND ELECTRONIC DEVICE

(71) Applicant: Samsung Display Co., Ltd., Yongin-Si (KR)

(72) Inventors: JAEHYUNG CHO, Yongin-si (KR); ILNAM KIM, Yongin-si (KR); MINKYU WOO, Yongin-si (KR); DONG-HOON LEE, Yongin-si (KR); JAEYONG JANG, Yongin-si (KR); MINJAE JEONG, Yongin-si (KR)

(21) Appl. No.: 19/326,439

(22) Filed: Sep. 11, 2025

(30) Foreign Application Priority Data
Feb. 12, 2025 (KR) 10-2025-0018065

(51) Int. Cl. H10K 59/131; G09G 3/3225

(52) U.S. Cl. CPC H10K 59/131; G09G 3/3225; G09G 2300/0426; G09G 2310/0286; G09G 2330/021

(57) ABSTRACT

A display device includes a display panel including a light emitting element, a driver including a first gate emission signal generator that generates a first driving signal and a second gate emission signal generator that generates a second driving signal different from the first driving signal, a first conductive layer including a clock line electrically connected to each of the first gate emission signal generator and the second gate emission signal generator, and a second conductive layer disposed on the first conductive layer and defining a first opening overlapping at least a portion of the clock line in plan view and a second opening spaced apart from the first opening.

### CROSS-REFERENCE TO RELATED APPLICATION(S)

This application claims priority, under 35 USC § 119, to Korean Patent Application No. 10-2025-0018065 filed on Feb. 12, 2025 in the Korean Intellectual Property Office (KIPO), the entire disclosure of which is incorporated by reference herein.

### BACKGROUND

### 1. Field

Embodiments relate to a display device and an electronic device including the display device.

### 2. Description of the Related Art

A display device may include a display panel and a driver that drives the display panel. The driver may include a gate driver that provides a gate signal, a data driver that provides data voltage, and an emission driver for providing an emission signal.

The display panel may include a power supply electrode connected to a cathode electrode of a pixel to stably supply a voltage to the cathode electrode, and a clock line connected to the gate driver and the emission driver. When the power supply electrode and the clock line overlap in plan view, parasitic capacitance may be generated between the power supply electrode and the clock line.

### SUMMARY

Embodiments provide a display device with reduced power consumption.

Embodiments provide an electronic device including the display device.

A display device according to an embodiment of the present disclosure includes a display panel including a light emitting element, a driver including a first gate emission signal generator that generates a first driving signal and a second gate emission signal generator that generates a second driving signal different from the first driving signal, a first conductive layer including a clock line electrically connected to each of the first gate emission signal generator and the second gate emission signal generator, and a second conductive layer disposed on the first conductive layer and defining a first opening overlapping at least a portion of the clock line in plan view and a second opening spaced apart from the first opening.

In an embodiment, the second gate emission signal generator may be adjacent to the first gate emission signal generator in a first direction, and the first gate emission signal generator and the second gate emission signal generator may be symmetrical with respect to a first virtual line extending in a second direction intersecting the first direction.

In an embodiment, the driver may include a plurality of stages arranged in rows, each of the plurality of stages may include the first gate emission signal generator and the second gate emission signal generator, and the clock line may include a first clock line connected to stages located in odd-numbered rows among the plurality of stages and a second clock line connected to stages located in even-numbered rows among the plurality of stages.

In an embodiment, the first opening may include a first sub-opening overlapping the first clock line in plan view and a second sub-opening overlapping the second clock line in plan view.

In an embodiment, the first sub-opening and the second sub-opening may symmetrical with respect to a second virtual line extending in the second direction.

In an embodiment, an area in which the first sub-opening and the first clock line overlap in plan view may be equal to an area in which the second sub-opening and the second clock line overlap in plan view.

In an embodiment, the first clock line may include a first extension portion extending in the second direction and a first protrusion portion protruding from the first extension portion, and the first sub-opening may overlap the first extension portion in plan view.

In an embodiment, the second clock line may include a second extension portion extending in the second direction and a second protrusion portion protruding from the second extension portion, and the second sub-opening may overlap the second extension portion in plan view.

In an embodiment, the second opening may include a third sub-opening and a fourth sub-opening spaced apart from the third sub-opening in the first direction and staggered with respect to the third sub-opening in the second direction.

In an embodiment, a planar shape of each of the first sub-opening and the second sub-opening may be different from a planar shape of each of the third sub-opening and the fourth sub-opening.

In an embodiment, the first opening may overlap the first clock line and the second clock line in plan view.

In an embodiment, the first conductive layer may further include a low voltage line disposed between the first clock line and the second clock line.

In an embodiment, the second conductive layer may overlap the first gate emission signal generator and the second gate emission signal generator in plan view.

In an embodiment, the second conductive layer may include a first area overlapping the clock line in plan view and a second area not overlapping the clock line in plan view, the first opening may be defined in the first area, and the second opening may be defined in the second area.

In an embodiment, the light emitting element may include a pixel electrode, a common electrode, and a light emitting layer between the pixel electrode and the common electrode, and the second conductive layer may be electrically connected to the common electrode.

An electronic device according to an embodiment of the present disclosure includes a display device and a processor that provides input image data and an input signal to the display device. The display device includes a display panel including a light emitting element, a driver including a first gate emission signal generator that generates a first driving signal and a second gate emission signal generator that generates a second driving signal different from the first driving signal, a first conductive layer including a clock line electrically connected to each of the first gate emission signal generator and the second gate emission signal generator, and a second conductive layer disposed on the first conductive layer and defining a first opening overlapping at least a portion of the clock line in plan view and a second opening spaced apart from the first opening.

In an embodiment, the second gate emission signal generator may be adjacent to the first gate emission signal generator in a first direction, and the first gate emission signal generator and the second gate emission signal generator may be symmetrical with respect to a virtual line extending in a second direction intersecting the first direction.

In an embodiment, the clock line may include a first clock line and a second clock line spaced apart from the first clock line in the first direction, and the first opening may include a first sub-opening overlapping the first clock line in plan view and a second sub-opening overlapping the second clock line in plan view.

In an embodiment, the first sub-opening and the second sub-opening may be symmetrical with respect to a virtual line extending in the second direction.

In an embodiment, an area in which the first sub-opening and the first clock line overlap in plan view may be equal to an area in which the second sub-opening and the second clock line overlap in plan view.

In a display device according to embodiments of the present disclosure, the display device may include a conductive layer defining an opening overlapping a first clock line and a second clock line in a plan view. An area of the first clock line overlapping the opening in the plan view and an area of the second clock line overlapping the opening in the plan view may be substantially the same. Accordingly, parasitic capacitance formed between the first and second clock lines and the conductive layer may be reduced, and thus power consumption of the display device may be reduced, and a deviation between parasitic capacitance formed between the first clock line and the conductive layer and parasitic capacitance formed between the second clock line and the conductive layer may be minimized.

### BRIEF DESCRIPTION OF THE DRAWINGS

FIG. 1 is a plan view illustrating a display device according to an embodiment of the present disclosure.

FIG. 2 is a block diagram illustrating the display device of FIG. 1.

FIG. 3 is a cross-sectional view taken along line I-I′ of FIG. 1.

FIG. 4 is a block diagram illustrating an example of a gate emission driver of FIG. 2.

FIG. 5 is a block diagram illustrating an example of a stage included in the gate emission driver of FIG. 4.

FIG. 6 is a circuit diagram illustrating an example of a stage included in the gate emission driver of FIG. 4.

FIGS. 7, 8, 9, 10, 11, 12, 13, 14, 15, 16, 17, 18, 19, 20, 21, and 22 are layout views illustrating a stage included in a gate emission driver according to an embodiment of the present disclosure.

FIGS. 23, 24, and 25 are layout views illustrating a stage included in a gate emission driver according to an embodiment of the present disclosure.

FIGS. 26, 27, and 28 are layout views illustrating a stage included in a gate emission driver according to an embodiment of the present disclosure.

FIG. 29 is a block diagram illustrating an electronic device according to an embodiment of the present disclosure.

FIG. 30 is a schematic view illustrating electronic devices according to embodiments of the present disclosure.

### DETAILED DESCRIPTION OF THE EMBODIMENTS

Hereinafter, embodiments of the present disclosure will be described in more detail with reference to the accompanying drawings. The same reference numerals are used for the same components in the drawings, and redundant descriptions of the same components will be omitted.

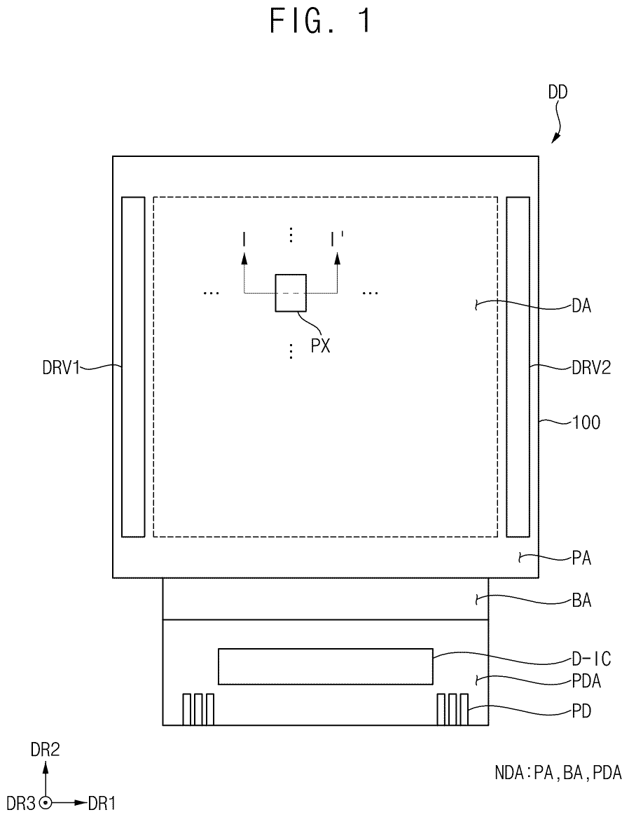

FIG. 1 is a plan view illustrating a display device according to an embodiment of the present disclosure.

Referring to FIG. 1, a display device DD may include a display panel 100.

The display panel 100 may include a display area DA and a non-display area NDA. The display area DA may be defined as an area that generates light to display an image. The display panel 100 may include pixels PX disposed in the display area DA. For example, pixels PX may be arranged in a matrix form along a first direction DR1 and a second direction DR2 intersecting the first direction DR1. For example, the second direction DR2 may be perpendicular to the first direction DR1. Each of pixels PX may generate light according to a driving signal. Accordingly, an image may be displayed in the display area DA. For example, the image may be displayed in a third direction DR3 intersecting each of the first direction DR1 and the second direction DR2. For example, the third direction DR3 may be perpendicular to each of the first direction DR1 and the second direction DR2.

The non-display area NDA may be adjacent to the display area DA. The non-display area NDA may at least partially surround the display area DA in a plan view. The non-display area NDA may be defined as an area that does not display an image. The non-display area NDA may include a peripheral area PA, a bending area BA, and a pad area PDA.

The peripheral area PA may be located around the display area DA. The peripheral area PA may at least partially surround the display area DA in a plan view.

The bending area BA may be located at one side of the peripheral area PA. For example, the bending area BA may extend from one side of the peripheral area PA, and may be bent in a downward direction. In other words, the display panel 100 may be bent with respect to a reference axis extending in the first direction DR1 in the bending area BA. In this case, the pad area PDA may be located on a bottom surface of the display device DD. When display panel 100 is in an unfolded state, the bending area BA may be located between the peripheral area PA and the pad area PDA.

The pad area PDA may be spaced apart from the peripheral area PA. For example, when the display panel 100 is in an unfolded state, the pad area PDA and the peripheral area PA may be spaced apart from each other in the second direction DR2. The bending area BA may be located between the pad area PDA and the peripheral area PA. The display panel 100 may further include pads PD disposed in the pad area PDA.

The display panel 100 may include a first driver DRV1, a second driver DRV2, and a driving chip D-IC disposed in the non-display area NDA.

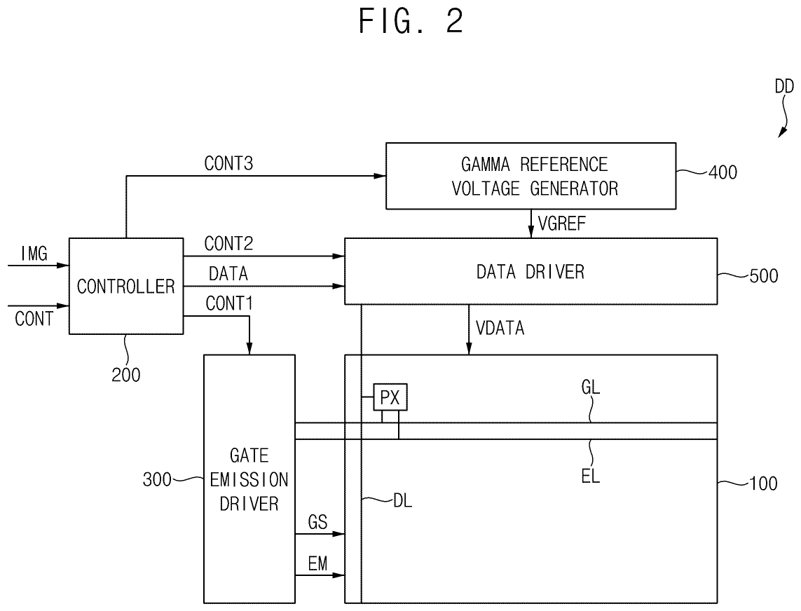

The first driver DRV1 and the second driver DRV2 may be disposed in the peripheral area PA of display panel 100. The first driver DRV1 and the second driver DRV2 may be spaced apart from each other. For example, the first driver DRV1 may be disposed in the peripheral area PA adjacent to a first side (e.g., a left side) of the display area DA, and the second driver DRV2 may be disposed in the peripheral area PA adjacent to a second side (e.g., a right side) of the display area DA. In an embodiment, each of the first driver DRV1 and the second driver DRV2 may correspond to a gate emission driver 300 of FIG. 2 to be described later. In an embodiment, one of the first driver DRV1 and the second driver DRV2 may be omitted.

The driving chip D-IC may be disposed in the pad area PDA of the display panel 100. The driving chip D-IC may be connected to the pads PD through an anisotropic conductive film. The driving chip D-IC may provide the driving signal to the pixels PX. The driving signal may include various signals for driving pixels PX, such as driving voltage, data voltage, or the like. The driving signal may be transmitted to the pixels PX through the driving chip D-IC and the pads PD. In an embodiment, the driving chip D-IC may correspond to a data driver 500 of FIG. 2.

Although not illustrated in FIG. 1, a printed circuit board may be disposed in the pad area PDA of the display panel 100. The printed circuit board may be connected to the pads PD through an anisotropic conductive film. For example, the printed circuit board may be a flexible printed circuit board (FPCB).

FIG. 2 is a block diagram illustrating the display device of FIG. 1.

Referring to FIGS. 1 and 2, the display device DD may include the display panel 100 and a panel driver that drives the display panel 100. The panel driver may include a controller 200, a gate emission driver 300, a gamma reference voltage generator 400, and a data driver 500.

The display panel 100 may include gate lines GL, data lines DL, emission lines EL, and the pixels PX. The pixels PX may be electrically connected to the gate lines GL, the data lines DL, and the emission lines EL, respectively. For example, each of the gate lines GL may extend in the first direction DR1, each of the emission lines EL may extend in the first direction DR1, and each of the data lines DL may extend in a second direction DR2.

The controller 200 may receive input image data IMG and an input signal CONT from an external device. For example, the input image data IMG may include red image data, green image data, and blue image data. For example, the input image data IMG may further include white image data. The input signal CONT may include a vertical sync signal, a horizontal sync signal, a data enable signal, a master clock signal, or the like.

The controller 200 may generate a first control signal CONT1, a second control signal CONT2, a third control signal CONT3, and a data signal DATA based on the input image data IMG and the input signal CONT. The controller 200 may output the first control signal CONT1 to the gate emission driver 300. The first control signal CONT1 may include a vertical start signal and a clock signal. The controller 200 may output the second control signal CONT2 and the data signal DATA to the data driver 500. The second control signal CONT2 may include a horizontal start signal and a load signal. The controller 200 may output the third control signal CONT3 to the gamma reference voltage generator 400.

The gate emission driver 300 may generate a gate signal GS and an emission signal EM in response to the first control signal CONT1. The gate emission driver 300 may output the gate signal GS to the gate lines GL. The gate emission driver 300 may also output the emission signal EM to the emission lines EL. For example, the gate signal GS may include a write gate signal, a compensation gate signal, an initialization gate signal, a bias gate signal, or the like. However, the present disclosure is not limited thereto.

In an embodiment, the gate emission driver 300 may be disposed in the peripheral area PA of the display panel 100. For example, the gate emission driver 300 may be mounted in the peripheral area PA of the display panel 100. The gate emission driver 300 may correspond to the first driver DRV1 and the second driver DRV2.

The gamma reference voltage generator 400 may generate the gamma reference voltage VGREF in response to the third control signal CONT3. The gamma reference voltage generator 400 may provide the gamma reference voltage VGREF to the data driver 500. For example, the gamma reference voltage generator 400 may be disposed in the controller 200 or in the data driver 500.

The data driver 500 may receive the second control signal CONT2 and the data signal DATA from the controller 200. The data driver 500 may receive the gamma reference voltage VGREF from the gamma reference voltage generator 400. The data driver 500 may convert the data signal DATA into an analog data voltage VDATA using the gamma reference voltage VGREF. The data driver 500 may output the data voltage VDATA to the data lines DL.

In an embodiment, the data driver 500 may be disposed in the pad area PDA of the display panel 100. For example, the data driver 500 may be mounted in the pad area PDA of the display panel 100. The data driver 500 may correspond to the driving chip D-IC.

For example, the controller 200 and the data driver 500 may be integrally formed. A driver module in which the controller 200 and the data driver 500 are integrally formed may be referred to as a timing controller embedded data driver (TED).

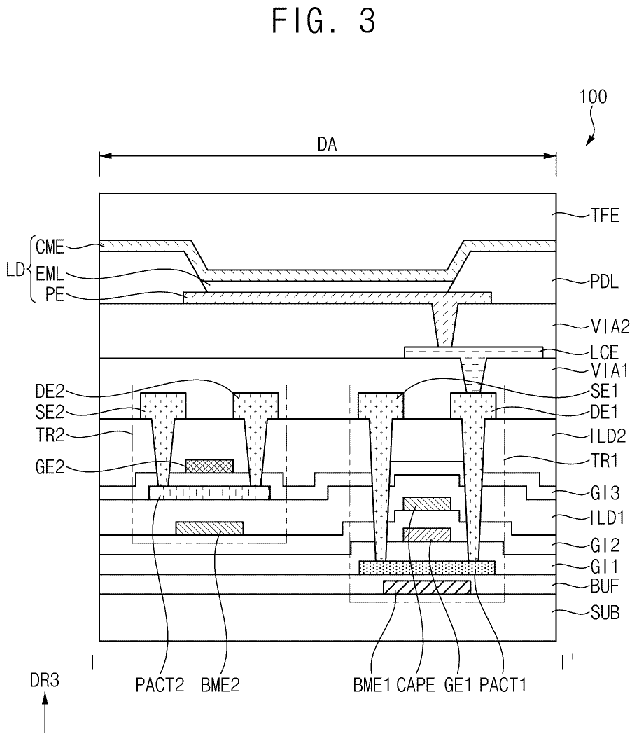

FIG. 3 is a cross-sectional view taken along line I-I′ of FIG. 1.

Referring to FIG. 3, the display panel 100 may include a substrate SUB, a buffer layer BUF, a first thin film transistor TR1, a first gate insulating layer GI1, a second gate insulating layer GI2, a capacitor electrode CAPE, a second thin film transistor TR2, a first interlayer insulating layer ILD1, a second interlayer insulating layer ILD2, a first via insulating layer VIA1, a connection electrode LCE, a second via insulating layer VIA2, a light emitting element LD, a pixel defining layer PDL, and an encapsulation layer TFE.

The first thin film transistor TR1 may include a first lower electrode BME1, a first pixel active pattern PACT1, a first pixel gate electrode GE1, a first pixel output electrode SE1, and a second pixel output electrode DE1. The first thin film transistor TR1 may be a transistor that is connected to the light emitting element LD through the connection electrode LCE. The second thin film transistor TR2 may include a second lower electrode BME2, a second pixel active pattern PACT2, a second pixel gate electrode GE2, a third pixel output electrode SE2, and a fourth pixel output electrode DE2. The light emitting element LD may include a pixel electrode PE, a light emitting layer EML, and a common electrode CME.

The substrate SUB may include a transparent material or an opaque material. For example, examples of materials that may be used as the substrate SUB may include glass, quartz, plastic, silicon, or the like. These may be used alone or in combination with each other.

The first lower electrode BME1 may be disposed on the substrate SUB. The first lower electrode BME1 may overlap the first pixel active pattern PACT1 in a plan view. For example, the first lower electrode BME1 may function as a lower gate electrode of the first thin film transistor TR1. The first lower electrode BME1 may include a conductive material such as a metal, an alloy, a conductive metal nitride, a conductive metal oxide, a transparent conductive oxide, or the like. Examples of the conductive material that may be used as the first lower electrode BME1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The buffer layer BUF may be disposed on the substrate SUB, and may cover the first lower electrode BME1. The buffer layer BUF may prevent metal atoms or impurities from diffusing from the substrate SUB into upper components. In addition, the buffer layer BUF may improve flatness of a surface of the substrate SUB when the surface of the substrate SUB is not uniform. The buffer layer BUF may include an inorganic insulating material. Examples of the inorganic insulating material that may be used as the buffer layer BUF may include silicon oxide (SiOₓ), silicon nitride (SiNₓ), silicon oxynitride (SiOₓN_{y}), or the like. These may be used alone or in combination with each other. In an embodiment, the buffer layer BUF may be omitted.

The first pixel active pattern PACT1 may be disposed on the substrate SUB. For example, the first pixel active pattern PACT1 may be disposed on the buffer layer BUF. The first pixel active pattern PACT1 may include a semiconductor material such as a silicon semiconductor material, an oxide semiconductor material, or the like. For example, the silicon semiconductor may include amorphous silicon, polycrystalline silicon, or the like. For example, the oxide semiconductor may include an oxide of at least one selected from indium (In), gallium (Ga), tin (Sn), zirconium (Zr), vanadium (V), hafnium (Hf), cadmium (Cd), germanium (Ge), chromium (Cr), titanium (Ti), and zinc (Zn). In an embodiment, the first pixel active pattern PACT1 may include a silicon semiconductor material.

The first gate insulating layer GI1 may be disposed on the buffer layer BUF, and may cover the first pixel active pattern PACT1. The first gate insulating layer GI1 may include an inorganic insulating material.

The first pixel gate electrode GE1 may be disposed on the first gate insulating layer GI1. The first pixel gate electrode GE1 may overlap the first pixel active pattern PACT1 in a plan view. For example, the first pixel gate electrode GE1 may function as an upper gate electrode of the first thin film transistor TR1. The first pixel gate electrode GE1 may include a conductive material such as a metal, an alloy, a conductive metal nitride, a conductive metal oxide, a transparent conductive oxide, or the like. These may be used alone or in combination with each other.

The second gate insulating layer GI2 may be disposed on the first gate insulating layer GI1, and may cover the first pixel gate electrode GE1. The second gate insulating layer GI2 may include an inorganic insulating material.

The capacitor electrode CAPE may be disposed on the second gate insulating layer GI2. The capacitor electrode CAPE may overlap the first pixel gate electrode GE1 in a plan view. For example, the capacitor electrode CAPE may form (or define) a capacitor together with the first pixel gate electrode GE1. The capacitor electrode CAPE may include a conductive material such as a metal, an alloy, a conductive metal nitride, a conductive metal oxide, a transparent conductive oxide, or the like. These may be used alone or in combination with each other.

The second lower electrode BME2 may be disposed on the second gate insulating layer GI2. For example, the second lower electrode BME2 may function as a lower gate electrode of the second thin film transistor TR2. The second lower electrode BME2 may include a conductive material such as a metal, an alloy, a conductive metal nitride, a conductive metal oxide, a transparent conductive oxide, or the like. These may be used alone or in combination with each other.

The first interlayer insulating layer ILD1 may be disposed on the second gate insulating layer GI2, and may cover the capacitor electrode CAPE and the second lower electrode BME2. The first interlayer insulating layer ILD1 may include an inorganic insulating material.

The second pixel active pattern PACT2 may be disposed on the first interlayer insulating layer ILD1. The second pixel active pattern PACT2 may include a semiconductor material such as a silicon semiconductor material, an oxide semiconductor material, or the like. In an embodiment, the second pixel active pattern PACT2 may include an oxide semiconductor material.

The third gate insulating layer GI3 may be disposed on the first interlayer insulating layer ILD1, and may cover the second pixel active pattern PACT2. The third gate insulating layer GI3 may include an inorganic insulating material.

The second pixel gate electrode GE2 may be disposed on the third gate insulating layer GI3. The second pixel gate electrode GE2 may overlap the second pixel active pattern PACT2 in a plan view. For example, the second pixel gate electrode GE2 may function as an upper gate electrode of the second thin film transistor TR2. The second pixel gate electrode GE2 may include a conductive material such as a metal, an alloy, a conductive metal nitride, a conductive metal oxide, a transparent conductive oxide, or the like. These may be used alone or in combination with each other.

The second interlayer insulating layer ILD2 may be disposed on the third gate insulating layer GI3, and may cover the second pixel gate electrode GE2. The second interlayer insulating layer ILD2 may include an inorganic insulating material.

The first pixel output electrode SE1 and the second pixel output electrode DE1 may be disposed on the second interlayer insulating layer ILD2. Each of the first pixel output electrode SE1 and the second pixel output electrode DE1 may be connected to the first pixel active pattern PACT1 through a contact hole penetrating a lower insulating layer (e.g., the first gate insulating layer GI1, the second gate insulating layer GI2, the first interlayer insulating layer ILD1, the third gate insulating layer GI3, and the second interlayer insulating layer ILD2).

Accordingly, the first thin film transistor TR1 including the first lower electrode BME1, the first pixel active pattern PACT1, the first pixel gate electrode GE1, the first pixel output electrode SE1, and the second pixel output electrode DE1 may be formed on the substrate SUB.

The third pixel output electrode SE2 and the fourth pixel output electrode DE2 may be disposed on the second interlayer insulating layer ILD2. Each of the third pixel output electrode SE2 and the fourth pixel output electrode DE2 may be connected to the second pixel active pattern PACT2 through a contact hole penetrating a lower insulating layer (e.g., the third gate insulating layer GI3 and the second interlayer insulating layer ILD2).

Accordingly, the second thin film transistor TR2 including the second lower electrode BME2, the second pixel active pattern PACT2, the second pixel gate electrode GE2, the third pixel output electrode SE2, and the fourth pixel output electrode DE2 may be formed on the substrate SUB (e.g., on the second gate insulating layer GI2).

The first via insulating layer VIA1 may be disposed on the second interlayer insulating layer ILD2, and may cover the first, second, third, and fourth pixel output electrodes SE1, DE1, SE2, and DE2. The first via insulating layer VIA1 may include an organic insulating material. Examples of the organic insulating material that may be used as the first via insulating layer VIA1 may include polyacrylic resin, polyimide resin, polyamide resin, siloxane resin, acrylic resin, epoxy resin, or the like. These may be used alone or in combination with each other.

The connection electrode LCE may be disposed on the first via insulating layer VIA1. The connection electrode LCE may be electrically connected to the first thin film transistor TR1. For example, the connection electrode LCE may be connected to the second pixel output electrode DE1 (or the first pixel output electrode SE1) through a contact hole penetrating a lower insulating layer (e.g., the first via insulating layer VIA1). The first thin film transistor TR1 may be electrically connected to the light emitting element LD through the connection electrode LCE. The connection electrode LCE may include a conductive material such as a metal, an alloy, a conductive metal nitride, a conductive metal oxide, a transparent conductive oxide, or the like. These may be used alone or in combination with each other.

The second via insulating layer VIA2 may be disposed on the first via insulating layer VIA1, and may cover the connection electrode LCE. The second via insulating layer VIA2 may include an organic insulating material.

The pixel electrode PE may be disposed on the second via insulating layer VIA2. The pixel electrode PE may be connected to the connection electrode LCE through a contact hole penetrating a lower insulating layer (e.g., the second via insulating layer VIA2). The pixel electrode PE may include a conductive material such as a metal, an alloy, a conductive metal nitride, a conductive metal oxide, a transparent conductive oxide, or the like. These may be used alone or in combination with each other. For example, the pixel electrode PE may operate as an anode.

The pixel defining layer PDL may be disposed on the second via insulating layer VIA2. The pixel defining layer PDL may cover an edge of the pixel electrode PE, and may expose at least a portion of an upper surface of the pixel electrode PE. The pixel defining layer PDL may include an organic insulating material and/or an inorganic insulating material.

The light emitting layer EML may be disposed on the pixel electrode PE. The light emitting layer EML may emit light of a selected color (e.g., red, green, or blue). In an embodiment, the light emitting layer EML may include at least one of an organic light emitting material and a quantum dot. For example, the light emitting layer EML may have a single-layer structure including one light emitting layer or a multi-layer structure including a plurality of light emitting layers.

The common electrode CME may be disposed on the pixel defining layer PDL and the light emitting layer EML, and may cover the pixel defining layer PDL and the light emitting layer EML. The common electrode CME may include a conductive material such as a metal, an alloy, a conductive metal nitride, a conductive metal oxide, a transparent conductive oxide, or the like. These may be used alone or in combination with each other. For example, the common electrode CME may function as a cathode.

Accordingly, the light emitting element LD including the pixel electrode PE, the light emitting layer EML, and the common electrode CME may be formed on the substrate SUB (e.g., on the second via insulating layer VIA2).

The encapsulation layer TFE may be disposed on the common electrode CME. The encapsulation layer TFE may prevent impurities, moisture, or the like from penetrating into the light emitting element LD from outside. The encapsulation layer TFE may include at least one inorganic encapsulation layer and at least one organic encapsulation layer.

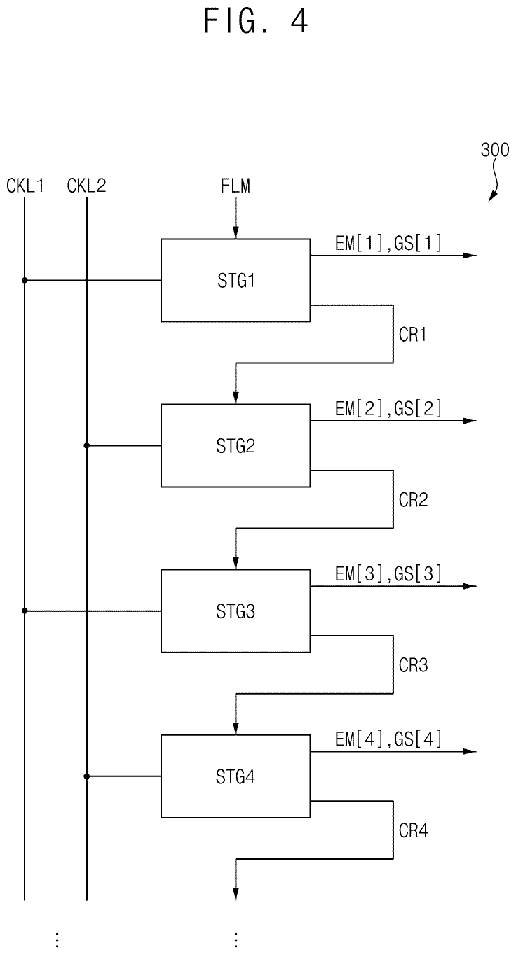

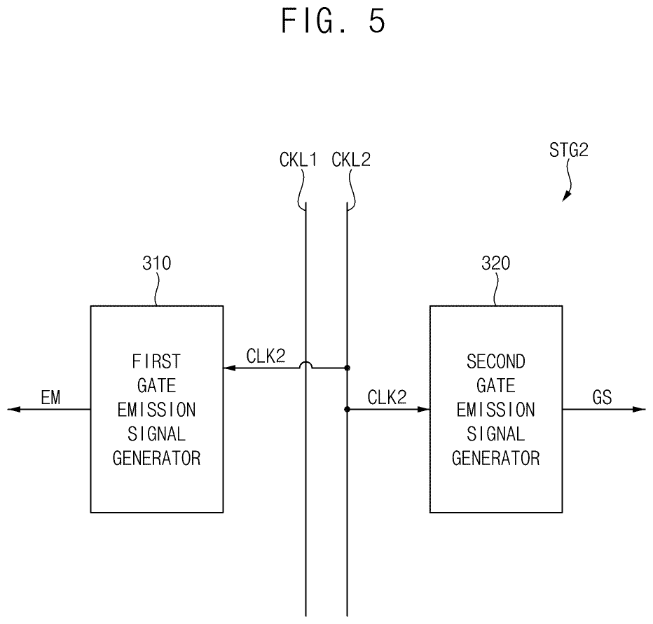

FIG. 4 is a block diagram illustrating an example of a gate emission driver of FIG. 2. FIG. 5 is a block diagram illustrating an example of a stage included in the gate emission driver of FIG. 4.

Referring to FIGS. 1, 4, and 5, the gate emission driver 300 may include a plurality of stages STG1, STG2, STG3, STG4, . . . , a first clock line CKL1, and a second clock line CKL2.

The stages STG1, STG2, STG3, STG4, . . . may be arranged in a column direction (e.g., the second direction DR2), with each stage being in its own row. For example, the first stage STG1 may be located in a first row, and may generate driving signals output to pixels PX arranged in the first row. The second stage STG2 may be located in a second row, and may generate driving signals output to pixels PX arranged in the second row. The third stage STG3 may be located in a third row, and may generate driving signals output to pixels PX arranged in the third row. The fourth stage STG4 may be located in a fourth row, and may generate driving signals output to pixels PX arranged in the fourth row.

Each of the first clock line CKL1 and the second clock line CKL2 may extend in the column direction (e.g., the second direction DR2). The first clock line CKL1 may output a first clock signal, and the second clock line CKL2 may output a second clock signal CLK2. The first clock line CKL1 and the second clock line CKL2 may be alternately connected to the stages STG1, STG2, STG3, STG4, . . . . For example, stages located in odd-numbered rows may be connected to the first clock line CKL1, and stages located in even-numbered rows may be connected to the second clock line CKL2. For example, as illustrated in FIG. 4, the first stage STG1 and the third stage STG3 may be connected to the first clock line CKL1, and the second stage STG2 and the fourth stage STG4 may be connected to the second clock line CKL2.

The first stage STG1 may receive a vertical start signal FLM as an input signal, and subsequent stages STG2, STG3, STG4, . . . may receive carry signals CR1, CR2, CR3, CR4, . . . of respective previous stages as input signals. For example, the second stage STG2 may receive a first carry signal CR1, the third stage STG3 may receive a second carry signal CR2, and the fourth stage STG4 may receive a third carry signal CR3.

In an embodiment, each of the stages STG1, STG2, STG3, STG4, . . . may generate two different types of driving signals among the emission signal EM and the gate signal GS described above with reference to FIG. 2 (e.g., the write gate signal, the compensation gate signal, the initialization gate signal, the bias gate signal, or the like).

In an embodiment, as illustrated in FIG. 5, each of the stages STG1, STG2, STG3, STG4, . . . may generate two different types of driving signals. For example, each of the stages STG1, STG2, STG3, STG4, . . . may generate the emission signal EM and the gate signal GS.

For example, the first stage STG1 may generate the first carry signal CR1, a first emission signal EM[1], and a first gate signal GS[1] based on the vertical start signal FLM. Each of the first emission signal EM[1] and the first gate signal GS[1] may be applied to the pixels PX arranged in the first row. For example, the second stage STG2 may generate the second carry signal CR2, a second emission signal EM[2], and a second gate signal GS[2] based on the first carry signal CR1. Each of the second emission signal EM[2] and the second gate signal GS[2] may be applied to the pixels PX arranged in the second row. The third stage STG3 may generate the third carry signal CR3, a third emission signal EM[3], and a third gate signal GS[3] based on the second carry signal CR2. Each of the third emission signal EM[3] and the third gate signal GS[3] may be applied to the pixels PX arranged in the third row. The fourth stage STG4 may generate a fourth carry signal CR4, a fourth emission signal EM[4], and a fourth gate signal GS[4] based on the third carry signal CR3. Each of the fourth emission signal EM[4] and the fourth gate signal GS[4] may be applied to the pixels PX arranged in the fourth row.

In an embodiment, the emission signals EM[1], EM[2], EM[3], EM[4], . . . may correspond to the emission signal EM described above with reference to FIG. 2, and the gate signals GS[1], GS[2], GS[3], GS[4], . . . may correspond to the gate signal GS described above with reference to FIG. 2.

Each of the stages STG1, STG2, STG3, STG4, . . . may have substantially the same or similar structure. For example, each of the stages STG1, STG2, STG3, STG4, . . . may include a first gate emission signal generator 310 and a second gate emission signal generator 320.

Accordingly, hereinafter, a description will be given with reference to the second stage STG2, and a description of the remaining stages STG1, STG3, STG4, . . . will be omitted. Hereinafter, for convenience of explanation, the second emission signal EM[2] will be referred to as the emission signal EM, and the second gate signal GS[2] will be referred to as the gate signal GS.

As illustrated in FIG. 5, the second stage STG2 may include the first gate emission signal generator 310 and the second gate emission signal generator 320.

The first gate emission signal generator 310 may be connected to the second clock line CKL2. The first gate emission signal generator 310 may receive the second clock signal CLK2 through the second clock line CKL2.

The second gate emission signal generator 320 may be connected to the second clock line CKL2. In an embodiment, the second gate emission signal generator 320 may be connected to the second clock line CKL2 to which the first gate emission signal generator 310 is connected. The second gate emission signal generator 320 may receive the second clock signal CLK2 through the second clock line CKL2.

In an embodiment, the first gate emission signal generator 310 may generate a first driving signal among the emission signal EM and the gate signal GS described above with reference to FIG. 2. The second gate emission signal generator 320 may generate a second driving signal different from the first driving signal among the emission signal EM and the gate signal GS described above with reference to FIG. 2.

In an embodiment, the first gate emission signal generator 310 may generate the emission signal EM based on the second clock signal CLK2, and the second gate emission signal generator 320 may generate the gate signal GS based on the second clock signal CLK2.

In an embodiment, the first gate emission signal generator 310 and the second gate emission signal generator 320 may be connected to the same second clock line CKL2. That is, the first gate emission signal generator 310 and the second gate emission signal generator 320 may share the same clock line. Accordingly, integration density of the gate emission driver 300 may be improved. In addition, as the first gate emission signal generator 310 and the second gate emission signal generator 320 share the same clock line, an additional clock signal may not be output, and thus power consumption of the gate emission driver 300 may be reduced.

The gate emission driver 300 may correspond to the first driver DRV1 and the second driver DRV2. That is, each of the first driver DRV1 and the second driver DRV2 may include the first gate emission signal generator 310 and the second gate emission signal generator 320.

In an embodiment, a first driving signal generated by the first gate emission signal generator 310 of the first driver DRV1 may be the emission signal EM, and a second driving signal generated by the second gate emission signal generator 320 of the first driver DRV1 may be the gate signal GS. In addition, a first driving signal generated by the first gate emission signal generator 310 of the second driver DRV2 may be the gate signal GS different from the second driving signal of the first driver DRV1, and a second driving signal generated by the second gate emission signal generator 320 of the second driver DRV2 may be the gate signal GS different from the second driving signal of the first driver DRV1 and the first driving signal of the second driver DRV2.

For example, the first driving signal of the first driver DRV1 may be the emission signal EM, the second driving signal of the first driver DRV1 may be the bias gate signal among the gate signal GS, the first driving signal of the second driver DRV2 may be the compensation gate signal among the gate signal GS, and the second driving signal of the second driver DRV2 may be the initialization gate signal among the gate signal GS. However, the present disclosure is not limited thereto.

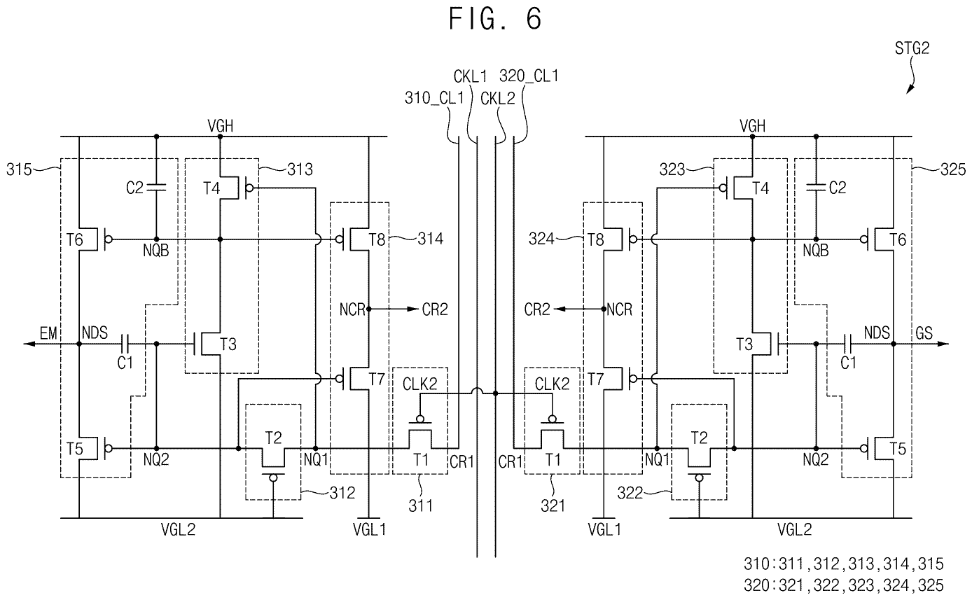

FIG. 6 is a circuit diagram illustrating an example of a stage included in the gate emission driver of FIG. 4.

Referring to FIGS. 4, 5, and 6, each stage (e.g., the second stage STG2) may include the first gate emission signal generator 310 and the second gate emission signal generator 320.

The first gate emission signal generator 310 may include an input block 311, a voltage limiting block 312, an inversion block 313, a carry signal output block 314, and a driving signal output block 315. The second gate emission signal generator 320 may include an input block 321, a voltage limiting block 322, an inversion block 323, a carry signal output block 324, and a driving signal output block 325. The first gate emission signal generator 310 and the second gate emission signal generator 320 may have substantially the same or similar and symmetrical circuit structures.

The input blocks 311 and 321 may receive an input signal (e.g., the first carry signal CR1). For example, the input block 311 of the first gate emission signal generator 310 may receive the first carry signal CR1 from a carry line 310_CL1 of the first gate emission signal generator 310. For example, the input block 321 of the second gate emission signal generator 320 may receive the first carry signal CR1 from a carry line 320_CL1 of the second gate emission signal generator 320.

The input blocks 311 and 321 may output the first carry signal CR1 to control nodes NQ1 and NQ2 in response to a clock signal (e.g., the second clock signal CLK2). The control nodes NQ1 and NQ2 may include a first control node NQ1 and a second control node NQ2.

The input blocks 311 and 321 may include a first transistor T1. The first transistor T1 may include a gate electrode that receives the second clock signal CLK2, a first electrode that receives the first carry signal CR1, and a second electrode connected to the first control node NQ1. In an embodiment, the first transistor T1 may be a p-type transistor.

The voltage limiting blocks 312 and 322 may limit voltage of the control nodes NQ1 and NQ2 based on a second low gate voltage VGL2. The voltage limiting blocks 312 and 322 may include a second transistor T2. The second transistor T2 may include a gate electrode that receives the second low gate voltage VGL2, a first electrode connected to the first control node NQ1, and a second electrode connected to the second control node NQ2. In an embodiment, the second transistor T2 may be a p-type transistor.

The inversion blocks 313 and 323 may invert the voltage of the control nodes NQ1 and NQ2 and output it to an inversion control node NQB. The inversion blocks 313 and 323 may include a third transistor T3 and a fourth transistor T4. The third transistor T3 may include a gate electrode connected to the second control node NQ2, a first electrode that receives the second low gate voltage VGL2, and a second electrode connected to the inversion control node NQB. The fourth transistor T4 may include a gate electrode connected to the first control node NQ1, a first electrode that receives a high gate voltage VGH, and a second electrode connected to the inversion control node NQB. In an embodiment, the third transistor T3 may be an n-type transistor, and the fourth transistor T4 may be a p-type transistor.

The carry signal output blocks 314 and 324 may output a carry signal (e.g., the second carry signal CR2). The carry signal output blocks 314 and 324 may output a first low gate voltage VGL1 to a carry output node NCR in response to a voltage of the second control node NQ2, and may output the high gate voltage VGH to the carry output node NCR in response to a voltage of the inversion control node NQB. In an embodiment, each of the first low gate voltage VGL1 and the second low gate voltage VGL2 may be lower than the high gate voltage VGH. In an embodiment, the second low gate voltage VGL2 may be lower than the first low gate voltage VGL1.

The carry signal output blocks 314 and 324 may include a seventh transistor T7 and an eighth transistor T8. The seventh transistor T7 may include a gate electrode connected to the second control node NQ2, a first electrode that receives the first low gate voltage VGL1, and a second electrode connected to the carry output node NCR. The eighth transistor T8 may include a gate electrode connected to the inversion control node NQB, a first electrode that receives the high gate voltage VGH, and a second electrode connected to the carry output node NCR. In an embodiment, each of the seventh transistor T7 and the eighth transistor T8 may be a p-type transistor.

The driving signal output blocks 315 and 325 may output a driving signal. In an embodiment, the driving signal output block 315 of the first gate emission signal generator 310 may output the emission signal EM, and the driving signal output block 325 of the second gate emission signal generator 320 may output the gate signal GS.

The driving signal output blocks 315 and 325 may output the second low gate voltage VGL2 to a driving output node NDS in response to voltage of the second control node NQ2, and may output the high gate voltage VGH to the driving output node NDS in response to voltage of the inversion control node NQB.

The driving signal output blocks 315 and 325 may include a fifth transistor T5 and a sixth transistor T6. The fifth transistor T5 may include a gate electrode connected to the second control node NQ2, a first electrode that receives the second low gate voltage VGL2, and a second electrode connected to the driving output node NDS. The sixth transistor T6 may include a gate electrode connected to the inversion control node NQB, a first electrode that receives the high gate voltage VGH, and a second electrode connected to the driving output node NDS. In an embodiment, each of the fifth transistor T5 and the sixth transistor T6 may be a p-type transistor.

In an embodiment, the driving signal output blocks 315 and 325 may further include a first capacitor C1 and a second capacitor C2. The first capacitor C1 may include a first electrode connected to the second control node NQ2 and a second electrode connected to the driving output node NDS. The second capacitor C2 may include a first electrode that receives the high gate voltage VGH and a second electrode connected to the inversion control node NQB.

In an embodiment, the seventh transistor T7 of the carry signal output blocks 314 and 324 and the fifth transistor T5 of the driving signal output blocks 315 and 325 may each be a p-type transistor. Accordingly, threshold voltages of the fifth transistor T5 and the seventh transistor T7 may be prevented from shifting in a negative direction. In addition, since it is not necessary to increase the sizes of the fifth transistor T5 and the seventh transistor T7 for mobility compensation of the fifth transistor T5 and the seventh transistor T7, dead space of the gate emission driver 300 may be reduced.

Although FIG. 6 illustrates that each of the first, second, third, fourth, fifth, sixth, seventh, and eighth transistors T1, T2, T3, T4, T5, T6, T7, and T8 includes only an upper gate electrode, the present disclosure is not limited thereto. In an embodiment, each of first, second, third, fourth, fifth, sixth, seventh, and eighth transistors T1, T2, T3, T4, T5, T6, T7, and T8 may further include a lower gate electrode.

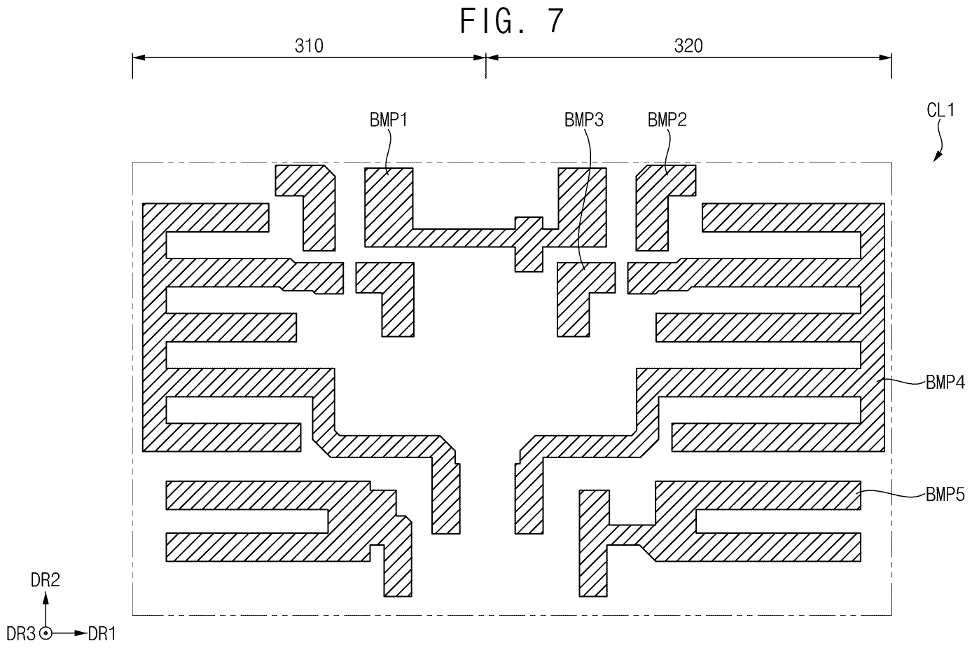

FIGS. 7, 8, 9, 10, 11, 12, 13, 14, 15, 16, 17, 18, 19, 20, 21, and 22 are layout views illustrating a stage included in a gate emission driver according to an embodiment of the present disclosure. For example, FIGS. 7 to 22 may be layout views illustrating an example of a stage included in the gate emission driver 300 of FIG. 4.

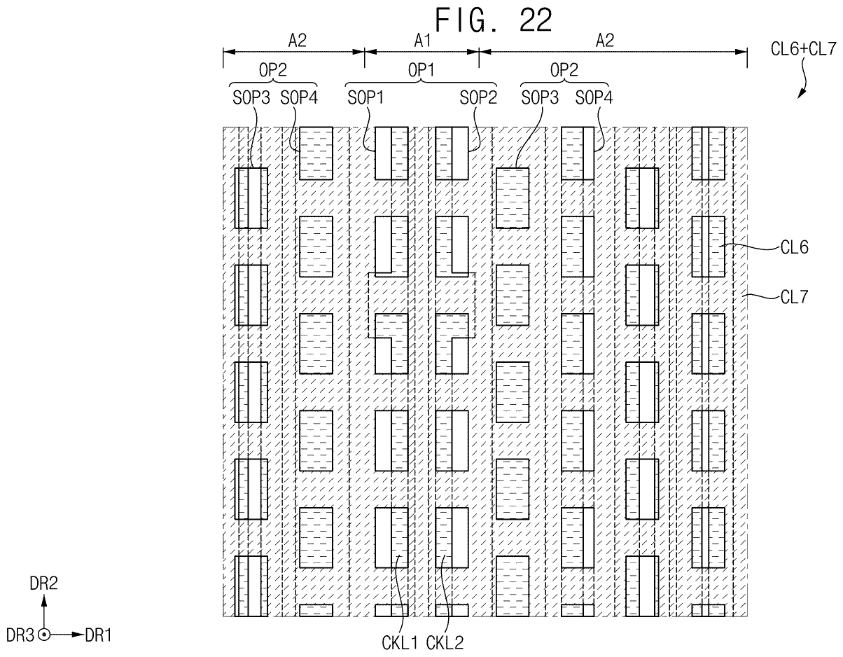

FIGS. 7 to 21 may be layout views illustrating a second stage (e.g., the second stage STG2 of FIG. 4) as an example of a stage included in a gate emission driver (e.g., the gate emission driver 300 of FIG. 4). FIG. 22 may be a layout view illustrating a portion of a plurality of stages included in the gate emission driver (e.g., the gate emission driver 300 of FIG. 4).

Referring to FIGS. 7 to 21, each stage included in the gate emission driver (e.g., the gate emission driver 300 of FIG. 4) may include the first gate emission signal generator 310 and the second gate emission signal generator 320.

In an embodiment, the second gate emission signal generator 320 may be adjacent to the first gate emission signal generator 310 in the first direction DR1. In an embodiment, the first gate emission signal generator 310 and the second gate emission signal generator 320 may be symmetrical with respect to a virtual line extending in the second direction DR2. The first gate emission signal generator 310 and the second gate emission signal generator 320 may have substantially similar structures symmetrical with respect to the virtual line. However, the present disclosure is not limited thereto.

FIG. 7 is a layout view illustrating a first conductive layer CL1.

Referring to FIGS. 3 and 7, the first conductive layer CL1 may be disposed on the substrate SUB. The first conductive layer CL1 may include a conductive material such as a metal, an alloy, a conductive metal nitride, a conductive metal oxide, a transparent conductive oxide, or the like. The first conductive layer CL1 may include a first lower conductive pattern BMP1, a second lower conductive pattern BMP2, a third lower conductive pattern BMP3, a fourth lower conductive pattern BMP4, and a fifth lower conductive pattern BMP5. The first, second, third, fourth, and fifth lower conductive patterns BMP1, BMP2, BMP3, BMP4, and BMP5 may be spaced apart from each other. The first, second, third, fourth, and fifth lower conductive patterns BMP1, BMP2, BMP3, BMP4, and BMP5 may be disposed in the same layer as the first lower electrode BME1 of FIG. 3.

The buffer layer BUF may be disposed on the first conductive layer CL1, and may cover the first, second, third, fourth, and fifth lower conductive patterns BMP1, BMP2, BMP3, BMP4, and BMP5. For example, the buffer layer BUF may include an inorganic insulating material.

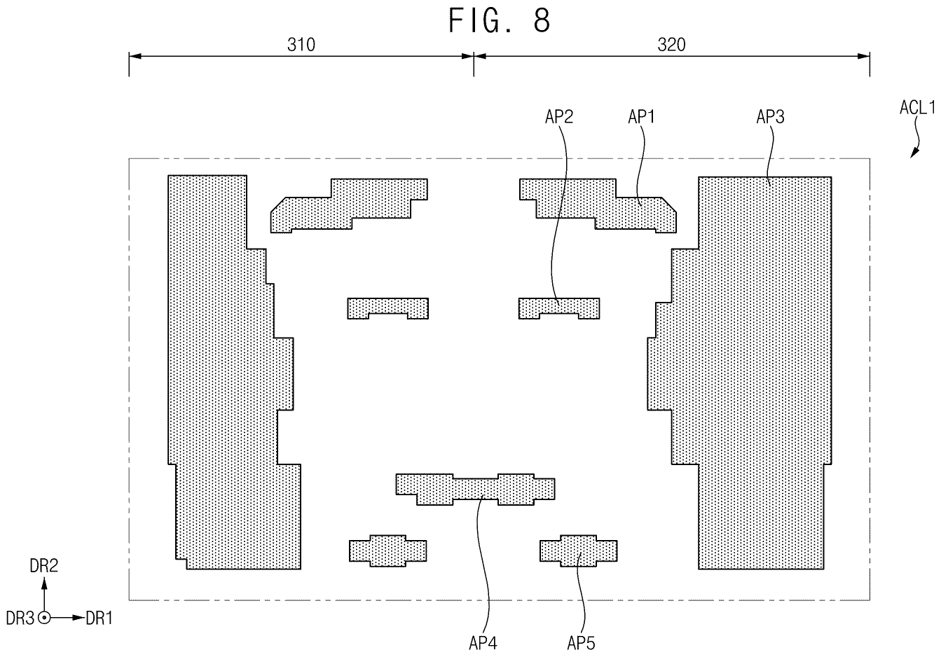

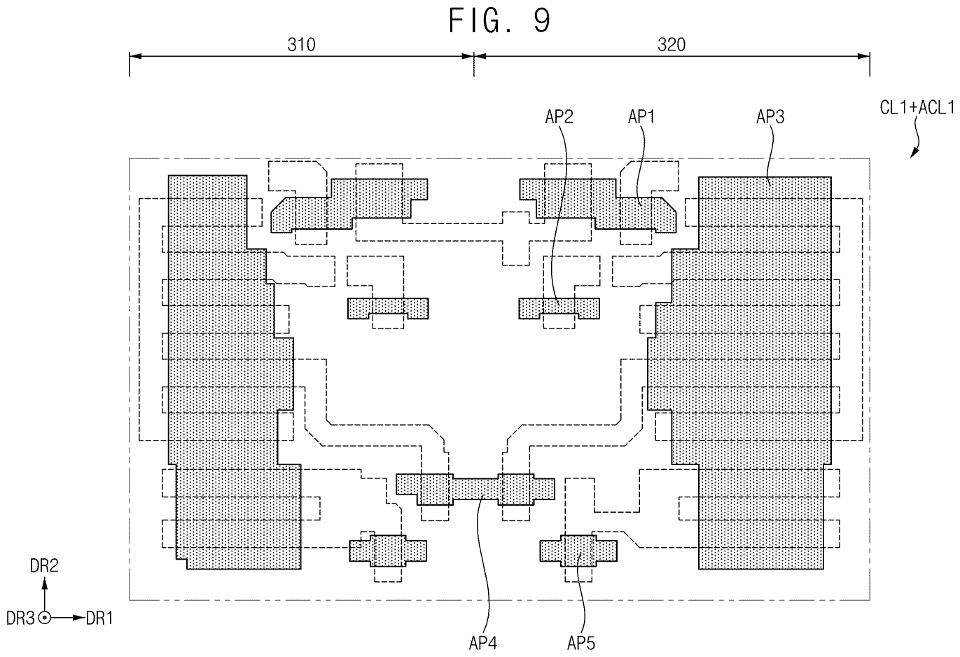

FIG. 8 is a layout view illustrating a first active layer ACL1. FIG. 9 is a layout view in which the first active layer ACL1 is further disposed on the first conductive layer CL1 of FIG. 7.

Referring further to FIGS. 8 and 9, the first active layer ACL1 may be disposed on the first conductive layer CL1. For example, the first active layer ACL1 may be disposed on the buffer layer BUF.

In an embodiment, the first active layer ACL1 may include a silicon semiconductor material. The silicon semiconductor material may include amorphous silicon, polycrystalline silicon, or the like.

The first active layer ACL1 may include a first active pattern AP1, a second active pattern AP2, a third active pattern AP3, a fourth active pattern AP4, and a fifth active pattern AP5. The first, second, third, fourth, and fifth active patterns AP1, AP2, AP3, AP4, and AP5 may be spaced apart from each other. The first, second, third, fourth, and fifth active patterns AP1, AP2, AP3, AP4, and AP5 may be disposed in the same layer as the first pixel active pattern PACT1 of FIG. 3.

The first lower conductive pattern BMP1 may at least partially overlap the first active pattern AP1 in a plan view. A portion of the first lower conductive pattern BMP1 overlapping the first active pattern AP1 in a plan view may be a lower gate electrode of the first transistor T1.

The second lower conductive pattern BMP2 may at least partially overlap the first active pattern AP1 in a plan view. A portion of the second lower conductive pattern BMP2 overlapping the first active pattern AP1 in a plan view may be a lower gate electrode of the second transistor T2.

The third lower conductive pattern BMP3 may at least partially overlap the second active pattern AP2 in a plan view. A portion of the third lower conductive pattern BMP3 overlapping the second active pattern AP2 in a plan view may be a lower gate electrode of the fourth transistor T4.

The fourth lower conductive pattern BMP4 may at least partially overlap each of the third active pattern AP3 and the fourth active pattern AP4 in a plan view. A first portion of the fourth lower conductive pattern BMP4 overlapping the third active pattern AP3 in a plan view may be a lower gate electrode of the fifth transistor T5. A second portion of the fourth lower conductive pattern BMP4 overlapping the fourth active pattern AP4 in a plan view may be a lower gate electrode of the seventh transistor T7.

The fifth lower conductive pattern BMP5 may at least partially overlap each of the third active pattern AP3 and the fifth active pattern AP5 in a plan view. A first portion of the fifth lower conductive pattern BMP5 overlapping the third active pattern AP3 in a plan view may be a lower gate electrode of the sixth transistor T6. A second portion of the fifth lower conductive pattern BMP5 overlapping the fifth active pattern AP5 in a plan view may be a lower gate electrode of the eighth transistor T8.

The first gate insulating layer GI1 may be disposed on the first active layer ACL1, and may cover the first, second, third, fourth, and fifth active patterns AP1, AP2, AP3, AP4, and AP5. For example, the first gate insulating layer GI1 may include an inorganic insulating material.

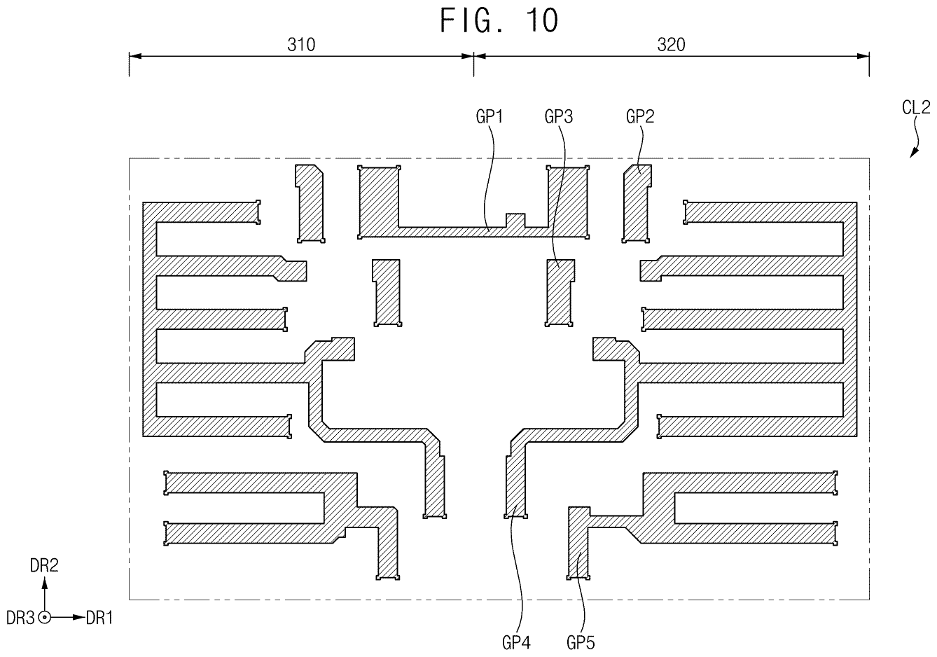

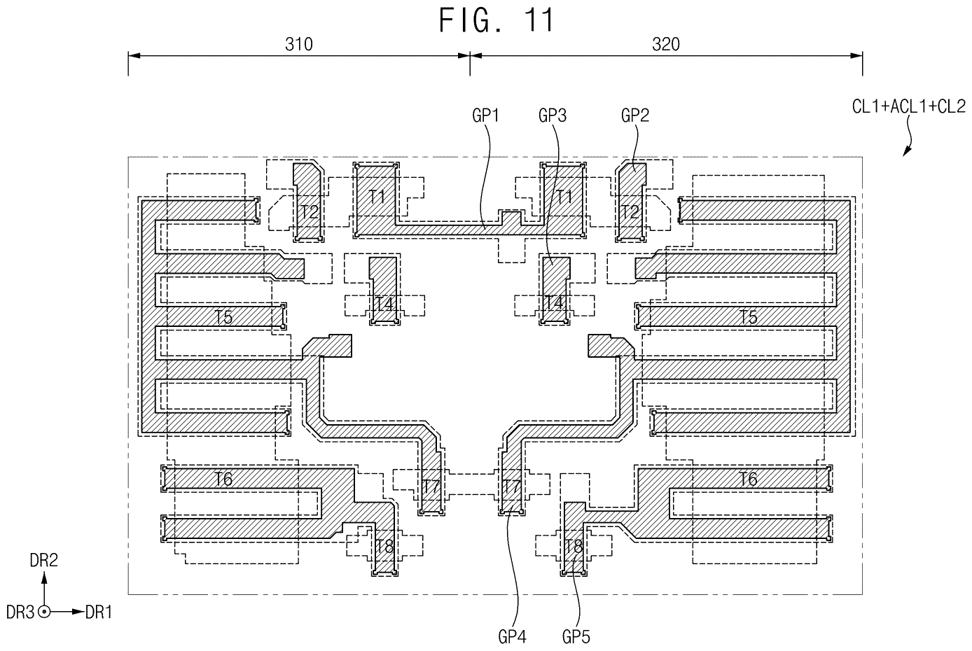

FIG. 10 is a layout view illustrating a second conductive layer CL2. FIG. 11 is a layout view in which the second conductive layer CL2 is further disposed on the first active layer ACL1 of FIG. 9.

Referring further to FIGS. 10 and 11, the second conductive layer CL2 may be disposed on the first active layer ACL1. For example, the second conductive layer CL2 may be disposed on the first gate insulating layer GI1.

The second conductive layer CL2 may include a conductive material such as a metal, an alloy, a conductive metal nitride, a conductive metal oxide, a transparent conductive oxide, or the like. The second conductive layer CL2 may include a first gate pattern GP1, a second gate pattern GP2, a third gate pattern GP3, a fourth gate pattern GP4, and a fifth gate pattern GP5. The first, second, third, fourth, and fifth gate patterns GP1, GP2, GP3, GP4, and GP5 may be spaced apart from each other. The first, second, third, fourth, and fifth gate patterns GP1, GP2, GP3, GP4, and GP5 may be disposed in the same layer as the first pixel gate electrode GE1 of FIG. 3.

The first gate pattern GP1 may at least partially overlap the first active pattern AP1 in a plan view. The first gate pattern GP1 may also at least partially overlap the first lower conductive pattern BMP1 in a plan view. A portion of the first gate pattern GP1 overlapping the first active pattern AP1 in a plan view may be an upper gate electrode of the first transistor T1.

The second gate pattern GP2 may at least partially overlap the first active pattern AP1 in a plan view. The second gate pattern GP2 may also at least partially overlap the second lower conductive pattern BMP2 in a plan view. A portion of the second gate pattern GP2 overlaps the first active pattern AP1 in a plan view may be an upper gate electrode of the second transistor T2.

The third gate pattern GP3 may at least partially overlap the second active pattern AP2 in a plan view. The third gate pattern GP3 may also at least partially overlap the third lower conductive pattern BMP3 in a plan view. A portion of the third gate pattern GP3 overlapping the second active pattern AP2 in a plan view may be an upper gate electrode of the fourth transistor T4.

The fourth gate pattern GP4 may at least partially overlap each of the third active pattern AP3 and the fourth active pattern AP4 in a plan view. The fourth gate pattern GP4 may also at least partially overlap the fourth lower conductive pattern BMP4 in a plan view. A first portion of the fourth gate pattern GP4 overlapping the third active pattern AP3 in a plan view may be an upper gate electrode of the fifth transistor T5. A second portion of the fourth gate pattern GP4 overlapping the fourth active pattern AP4 in a plan view may be an upper gate electrode of the seventh transistor T7.

The fifth gate pattern GP5 may at least partially overlap each of the third active pattern AP3 and the fifth active pattern AP5 in a plan view. The fifth gate pattern GP5 may also at least partially overlap the fifth lower conductive pattern BMP5 in a plan view. A first portion of the fifth gate pattern GP5 overlapping the third active pattern AP3 in a plan view may be an upper gate electrode of the sixth transistor T6. A second portion of the fifth gate pattern GP5 overlapping the fifth active pattern AP5 in a plan view may be an upper gate electrode of the eighth transistor T8.

The second gate insulating layer GI2 may be disposed on the second conductive layer CL2, and may cover the first, second, third, fourth, and fifth gate patterns GP1, GP2, GP3, GP4, and GP5. For example, the second gate insulating layer GI2 may include an inorganic insulating material.

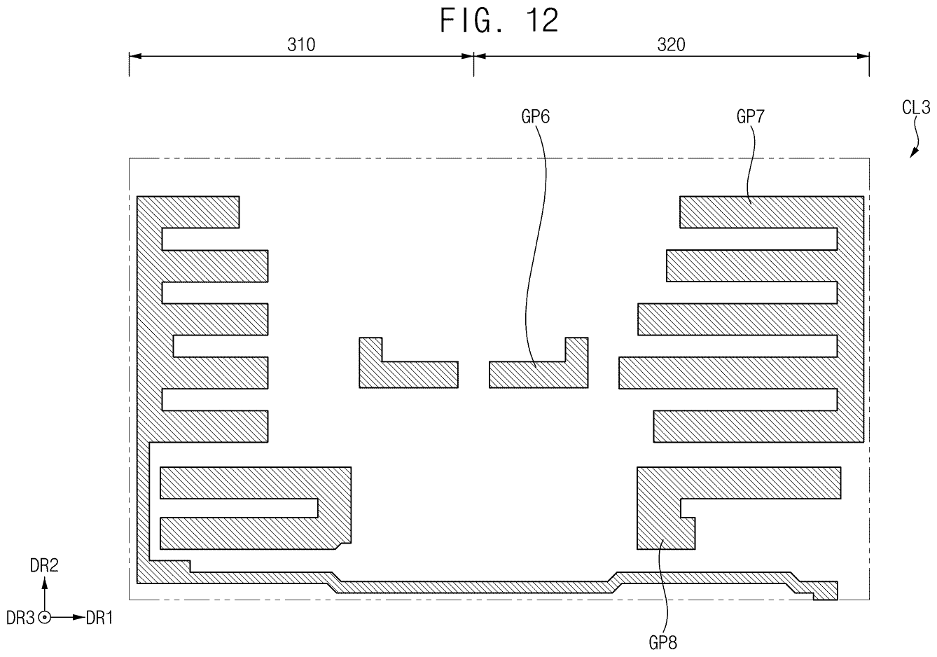

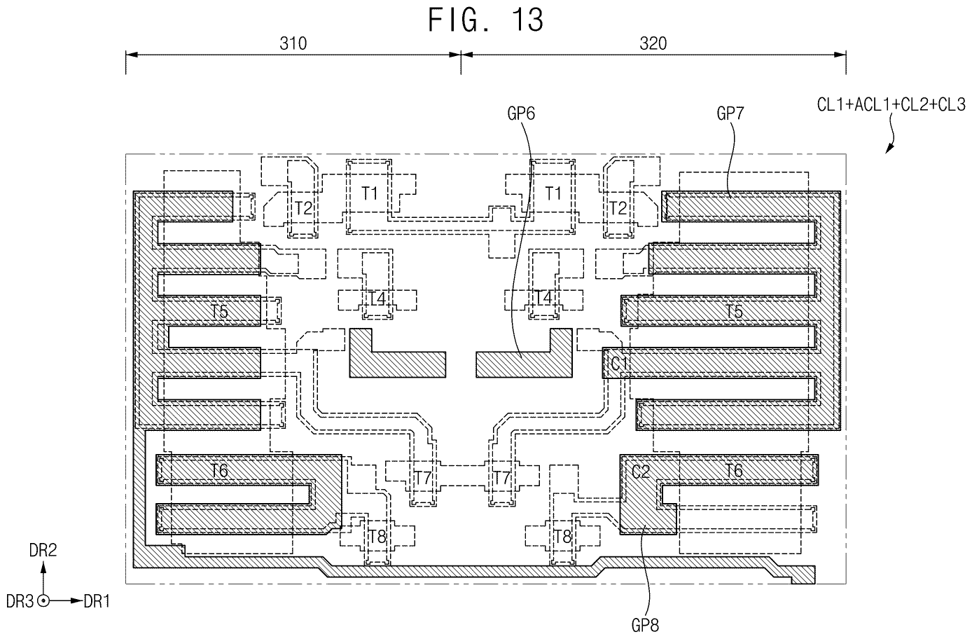

FIG. 12 is a layout view illustrating a third conductive layer CL3. FIG. 13 is a layout view in which the third conductive layer CL3 is further disposed on the second conductive layer CL2 of FIG. 11.

Referring further to FIGS. 12 and 13, the third conductive layer CL3 may be disposed on the second conductive layer CL2. For example, the third conductive layer CL3 may be disposed on the second gate insulating layer GI2.

The third conductive layer CL3 may include a conductive material such as a metal, an alloy, a conductive metal nitride, a conductive metal oxide, a transparent conductive oxide, or the like. The third conductive layer CL3 may include a sixth gate pattern GP6, a seventh gate pattern GP7, and an eighth gate pattern GP8. The sixth, seventh, and eighth gate patterns GP6, GP7, and GP8 may be spaced apart from each other. The sixth, seventh, and eighth gate patterns GP6, GP7, and GP8 may be disposed in the same layer as the capacitor electrode CAPE of FIG. 3.

The seventh gate pattern GP7 may at least partially overlap the fourth gate pattern GP4 in a plan view. The second gate insulating layer GI2 may be disposed between the seventh gate pattern GP7 and the fourth gate pattern GP4. The seventh gate pattern GP7 and the fourth gate pattern GP4 may form (or define) the first capacitor C1.

The eighth gate pattern GP8 may at least partially overlap the fifth gate pattern GP5 in a plan view. The second gate insulating layer GI2 may be disposed between the eighth gate pattern GP8 and the fifth gate pattern GP5. The eighth gate pattern GP8 and the fifth gate pattern GP5 may form (or define) the second capacitor C2.

The first interlayer insulating layer ILD1 may be disposed on the third conductive layer CL3, and may cover the sixth, seventh, and eighth gate patterns GP6, GP7, and GP8. For example, the first interlayer insulating layer ILD1 may include an inorganic insulating material.

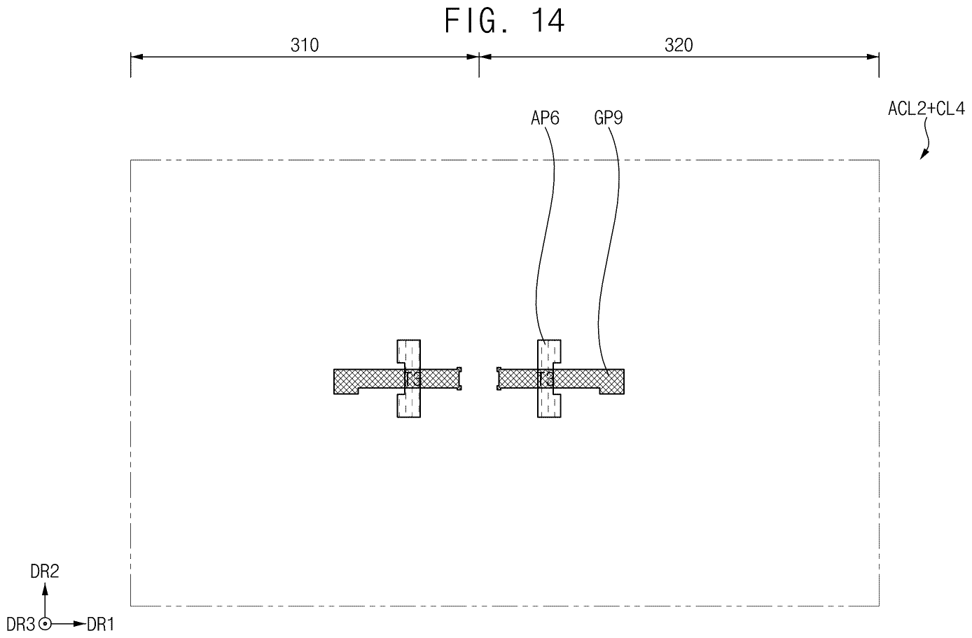

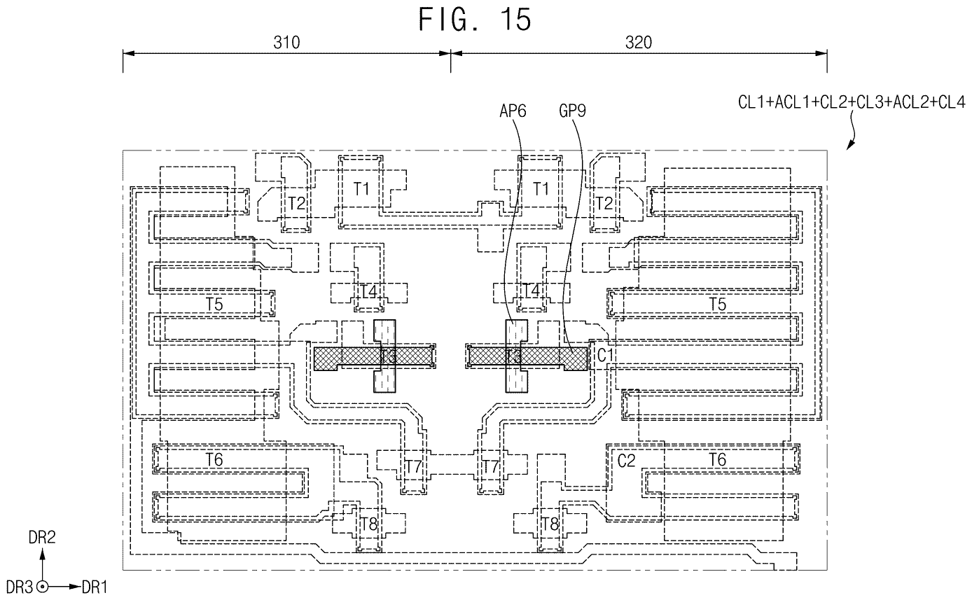

FIG. 14 is a layout view illustrating a second active layer ACL2 and a fourth conductive layer CL4. FIG. 15 is a layout view in which the second active layer ACL2 and the fourth conductive layer CL4 are further disposed on the third conductive layer CL3 of FIG. 13.

Referring further to FIGS. 14 and 15, the second active layer ACL2 may be disposed on the third conductive layer CL3. For example, the second active layer ACL2 may be disposed on the first interlayer insulating layer ILD1.

In an embodiment, the second active layer ACL2 may include an oxide semiconductor material. For example, the oxide semiconductor material may include at least one oxide of indium (In), gallium (Ga), tin (Sn), zirconium (Zr), vanadium (V), hafnium (Hf), cadmium (Cd), germanium (Ge), chromium (Cr), titanium (Ti), and zinc (Zn). The second active layer ACL2 may include a sixth active pattern AP6. The sixth active pattern AP6 may be disposed in the same layer as the second pixel active pattern PACT2 of FIG. 3.

The sixth gate pattern GP6 may at least partially overlap the sixth active pattern AP6 in a plan view. A portion of the sixth gate pattern GP6 overlapping the sixth active pattern AP6 in a plan view may be a lower gate electrode of the third transistor T3.

The third gate insulating layer GI3 may be disposed on the second active layer ACL2, and may cover the sixth active pattern AP6. For example, the third gate insulating layer GI3 may include an inorganic insulating material.

The fourth conductive layer CL4 may be disposed on the second active layer ACL2. For example, the fourth conductive layer CL4 may be disposed on the third gate insulating layer GI3.

The fourth conductive layer CL4 may include a conductive material such as a metal, an alloy, a conductive metal nitride, a conductive metal oxide, a transparent conductive oxide, or the like. The fourth conductive layer CL4 may include a ninth gate pattern GP9. The ninth gate pattern GP9 may be disposed in the same layer as the second pixel gate electrode GE2 of FIG. 3.

The ninth gate pattern GP9 may at least partially overlap the sixth active pattern AP6 in a plan view. The ninth gate pattern GP9 may also at least partially overlap the sixth gate pattern GP6 in a plan view. A portion of the ninth gate pattern GP9 overlapping the sixth active pattern AP6 in a plan view may be an upper gate electrode of the third transistor T3.

The second interlayer insulating layer ILD2 may be disposed on the fourth conductive layer CL4, and may cover the ninth gate pattern GP9. For example, the second interlayer insulating layer ILD2 may include an inorganic insulating material.

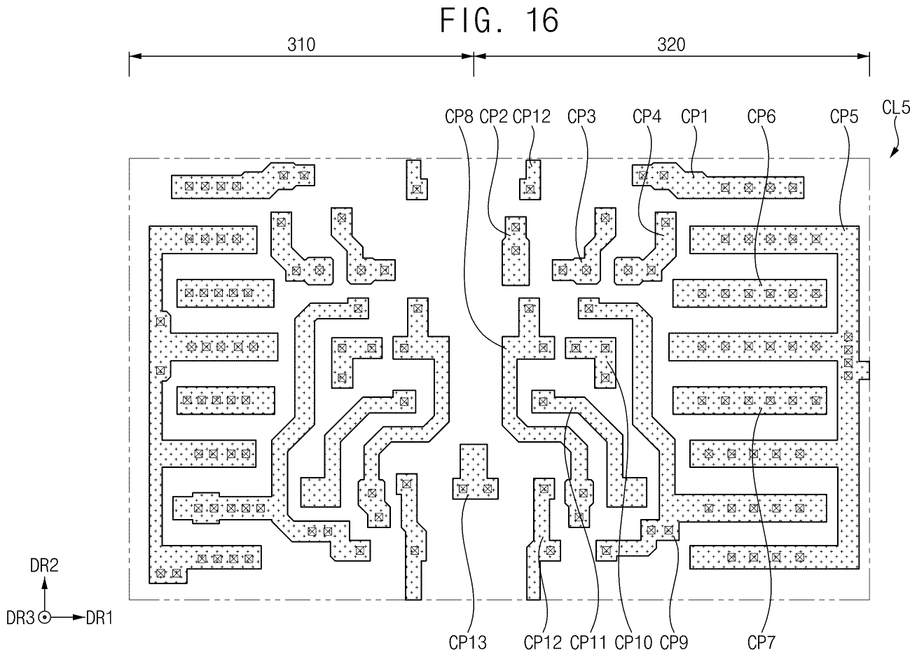

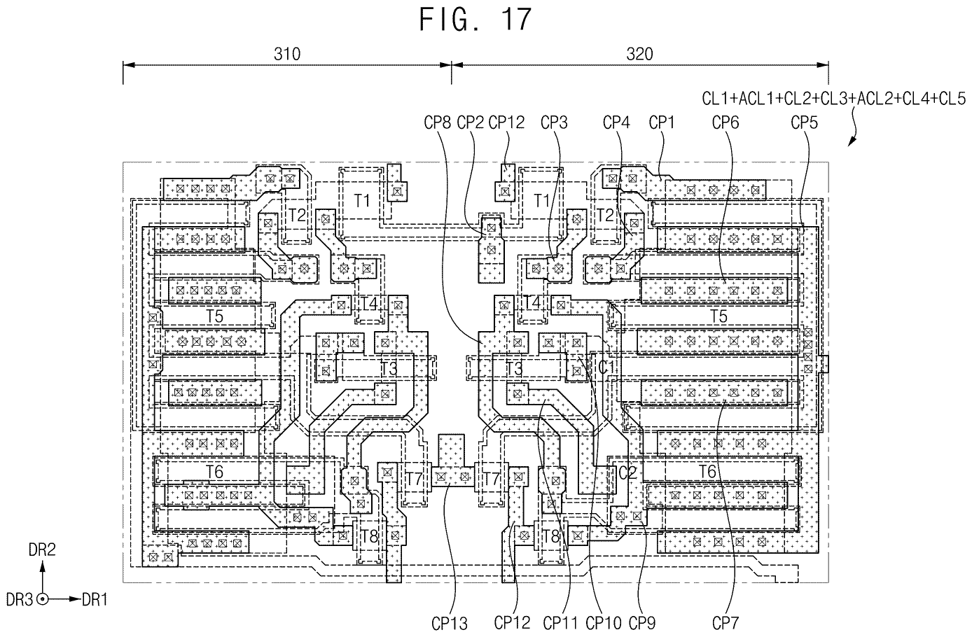

FIG. 16 is a layout view illustrating a fifth conductive layer CL5. FIG. 17 is a layout view in which the fifth conductive layer CL5 is further disposed on the fourth conductive layer CL4 of FIG. 15.

Referring further to FIGS. 6, 16, and 17, the fifth conductive layer CL5 may be disposed on the fourth conductive layer CL4. For example, the fifth conductive layer CL5 may be disposed on the second interlayer insulating layer ILD2.

The fifth conductive layer CL5 may include a conductive material such as a metal, an alloy, a conductive metal nitride, a conductive metal oxide, a transparent conductive oxide, or the like. The fifth conductive layer CL5 may include a first connection pattern CP1, a second connection pattern CP2, a third connection pattern CP3, a fourth connection pattern CP4, a fifth connection pattern CP5, a sixth connection pattern CP6, a seventh connection pattern CP7, an eighth connection pattern CP8, a ninth connection pattern CP9, a tenth connection pattern CP10, an eleventh connection pattern CP11, a twelfth connection pattern CP12, and a thirteenth connection pattern CP13. The first to thirteenth connection patterns CP1, CP2, CP3, CP4, CP5, CP6, CP7, CP8, CP9, CP10, CP11, CP12, and CP13 may be spaced apart from each other. The first to thirteenth connection patterns CP1, CP2, CP3, CP4, CP5, CP6, CP7, CP8, CP9, CP10, CP11, CP12, and CP13 may be disposed in the same layer as the first, second, third, and fourth pixel output electrodes SE1, DE1, SE2, and DE2 of FIG. 3.

The first connection pattern CP1 may receive the second low gate voltage VGL2. The first connection pattern CP1 may be connected to the second gate pattern GP2 through a contact hole. Accordingly, the first connection pattern CP1 may provide the second low gate voltage VGL2 to the upper gate electrode of the second transistor T2.

The second connection pattern CP2 may receive the second clock signal CLK2. The second connection pattern CP2 may be connected to the first gate pattern GP1 through a contact hole. Accordingly, the second connection pattern CP2 may provide the second clock signal CLK2 to the upper gate electrode of the first transistor T1.

The third connection pattern CP3 may be connected to the third gate pattern GP3 and the first active pattern AP1 through contact holes. Accordingly, the third connection pattern CP3 may electrically connect the upper gate electrode of the fourth transistor T4 and the second transistor T2.

The fourth connection pattern CP4 may be connected to the fourth gate pattern GP4 and the first active pattern AP1 through contact holes. Accordingly, the fourth connection pattern CP4 may electrically connect the upper gate electrode of the fifth transistor T5 and the second transistor T2.

The fifth connection pattern CP5 may be connected to the third active pattern AP3 through a contact hole. The fifth connection pattern CP5 may electrically connect the fifth transistor T5 and the sixth transistor T6.

The sixth connection pattern CP6 and the seventh connection pattern CP7 may receive the second low gate voltage VGL2. Each of the sixth connection pattern CP6 and the seventh connection pattern CP7 may be connected to the third active pattern AP3 through a contact hole. Accordingly, the sixth connection pattern CP6 and the seventh connection pattern CP7 may provide the second low gate voltage VGL2 to the fifth transistor T5.

The eighth connection pattern CP8 may be connected to the second active pattern AP2, the sixth active pattern AP6, and the fifth gate pattern GP5 through contact holes. Accordingly, the eighth connection pattern CP8 may electrically connect the upper gate electrode of the eighth transistor T8, the third transistor T3, and the fourth transistor T4.

The ninth connection pattern CP9 may receive the high gate voltage VGH. The ninth connection pattern CP9 may be connected to the second active pattern AP2, the third active pattern AP3, the eighth gate pattern GP8, and the fifth active pattern AP5 through contact holes. Accordingly, the ninth connection pattern CP9 may provide the high gate voltage VGH to the fourth transistor T4, the sixth transistor T6, the second capacitor C2, and the eighth transistor T8.

The tenth connection pattern CP10 may be connected to the fourth gate pattern GP4 and the ninth gate pattern GP9 through contact holes. Accordingly, the tenth connection pattern CP10 may electrically connect the upper gate electrode of the seventh transistor T7 and the upper gate electrode of the third transistor T3.

The eleventh connection pattern CP11 may receive the second low gate voltage VGL2. The eleventh connection pattern CP11 may be connected to the sixth active pattern AP6 through a contact hole. Accordingly, the eleventh connection pattern CP11 may provide the second low gate voltage VGL2 to the third transistor T3.

The twelfth connection pattern CP12 may be connected to the fourth active pattern AP4, the fifth active pattern AP5, and the first active pattern AP1 of next row through contact holes. Accordingly, the twelfth connection pattern CP12 may electrically connect the seventh transistor T7 and the eighth transistor T8. In addition, the twelfth connection pattern CP12 may provide a carry signal to the first transistor T1 of the next row. That is, the twelfth connection pattern CP12 included in a stage of N-th row (where N is a natural number) may provide the carry signal to the first transistor T1 included in a stage of (N+1)-th row.

The thirteenth connection pattern CP13 may receive the first low gate voltage VGL1. The thirteenth connection pattern CP13 may be connected to the fourth active pattern AP4 through a contact hole. Accordingly, the thirteenth connection pattern CP13 may provide the first low gate voltage VGL1 to the seventh transistor T7.

The first via insulating layer VIA1 may be disposed on the fifth conductive layer CL5, and may cover the first to thirteenth connection patterns CP1, CP2, CP3, CP4, CP5, CP6, CP7, CP8, CP9, CP10, CP11, CP12, and CP13. For example, the first via insulating layer VIA1 may include an organic insulating material.

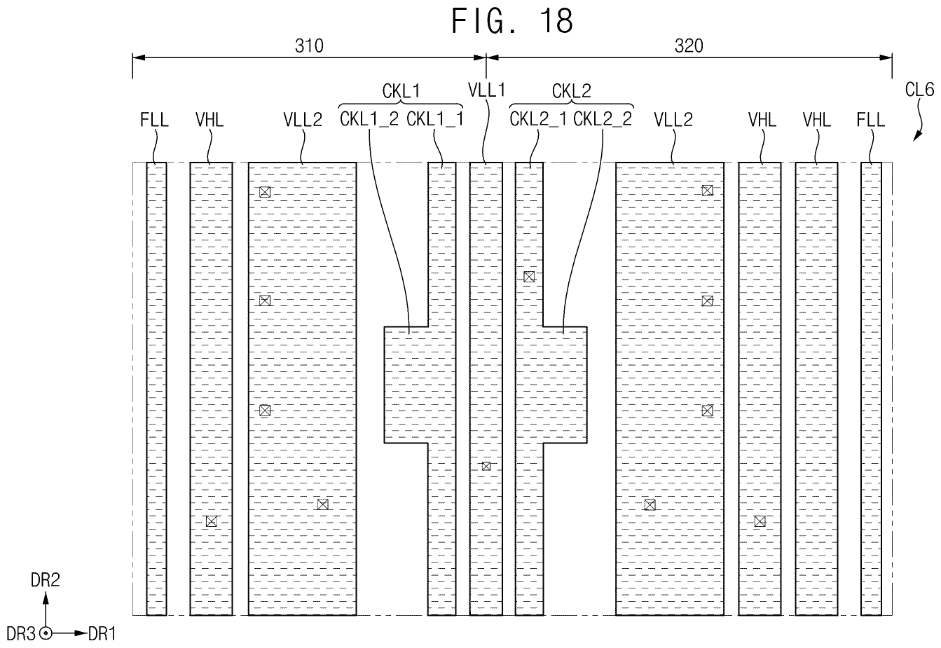

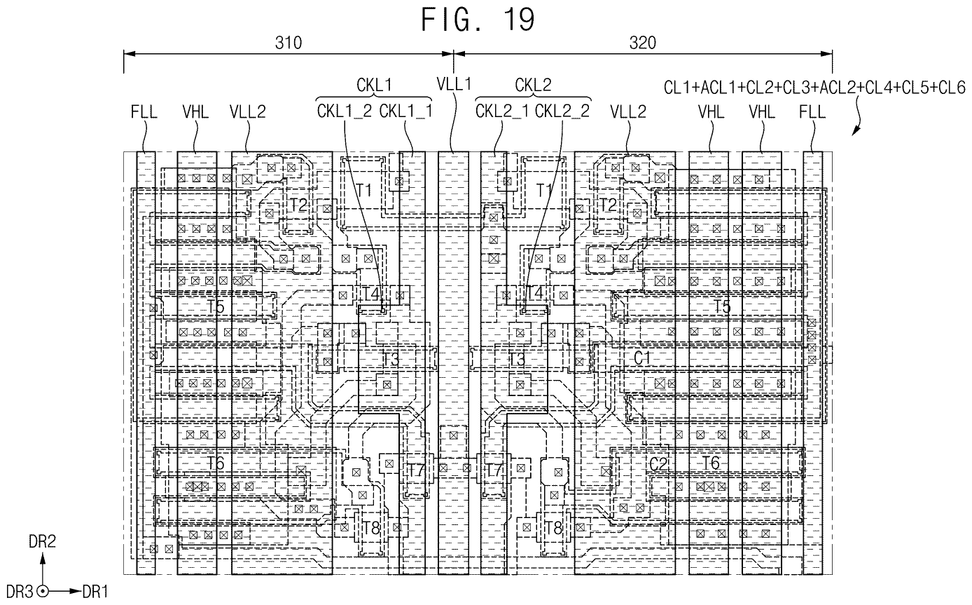

FIG. 18 is a layout view illustrating a sixth conductive layer CL6. FIG. 19 is a layout view in which the sixth conductive layer CL6 is further disposed on the fifth conductive layer CL5 of FIG. 17.

Referring further to FIGS. 18 and 19, the sixth conductive layer CL6 may be disposed on the fifth conductive layer CL5. For example, the sixth conductive layer CL6 may be disposed on the first via insulating layer VIA1.

The sixth conductive layer CL6 may include a conductive material such as a metal, an alloy, a conductive metal nitride, a conductive metal oxide, a transparent conductive oxide, or the like. The sixth conductive layer CL6 may include a first low voltage line VLL1, the first clock line CKL1, the second clock line CKL2, a second low voltage line VLL2, a high voltage line VHL, and an initiation signal line FLL. The first low voltage line VLL1, the first clock line CKL1, the second clock line CKL2, the second low voltage line VLL2, the high voltage line VHL, and the initiation signal line FLL may be spaced apart from one another. For example, each of the first low voltage line VLL1, the first clock line CKL1, the second clock line CKL2, the second low voltage line VLL2, the high voltage line VHL, and the initiation signal line FLL may extend in the second direction DR2.

For example, the first low voltage line VLL1, the first clock line CKL1, the second clock line CKL2, the second low voltage line VLL2, the high voltage line VHL, and the initiation signal line FLL may be disposed in the same layer as the connection electrode LCE of FIG. 3.

The first gate emission signal generator 310 and the second gate emission signal generator 320 may be distinguished based on the first low voltage line VLL1. For example, the first low voltage line VLL1 may be disposed between the first gate emission signal generator 310 and the second gate emission signal generator 320. The second clock line CKL2 may be spaced apart from the first clock line CKL1 in the first direction DR1, and the first low voltage line VLL1 may be disposed between the first clock line CKL1 and the second clock line CKL2 in a plan view.

In an embodiment, the first gate emission signal generator 310 and the second gate emission signal generator 320 may be line-symmetric with respect to the first low voltage line VLL1. The first gate emission signal generator 310 and the second gate emission signal generator 320 may have substantially similar or identical structures, being symmetric with respect to a virtual line extending in the second direction DR2. However, the present disclosure is not limited thereto, and the first gate emission signal generator 310 and the second gate emission signal generator 320 may not be line-symmetric with respect to the first low voltage line VLL1, and each of the first gate emission signal generator 310 and the second gate emission signal generator 320 may have various structures.

The first low voltage line VLL1 may be connected to the thirteenth connection pattern CP13 through a contact hole. The first low voltage line VLL1 may output the first low gate voltage VGL1 to the thirteenth connection pattern CP13.

In an embodiment, the first gate emission signal generator 310 and the second gate emission signal generator 320 may be connected to the same first low voltage line VLL1. For example, the first low voltage line VLL1 may be connected to the seventh transistor T7 of the first gate emission signal generator 310 and the seventh transistor T7 of the second gate emission signal generator 320 through the thirteenth connection pattern CP13. Accordingly, the first low gate voltage VGL1 may be applied to the seventh transistor T7 of the first gate emission signal generator 310 and the seventh transistor T7 of the second gate emission signal generator 320 through the first low voltage line VLL1 and the thirteenth connection pattern CP13.

For example, the first clock line CKL1 may overlap the first gate emission signal generator 310 in a plan view. FIGS. 7 to 21 are layout views illustrating the second stage (e.g., the second stage STG2 of FIG. 4) as an example of a stage included in the gate emission driver (e.g., the gate emission driver 300 of FIG. 4), and thus in FIGS. 18 and 19, the first clock line CKL1 may not be connected to other patterns.

In an embodiment, the first clock line CKL1 may include a first extension portion CKL1_1 extending in the second direction DR2 and a first protrusion portion CKL1_2 protruding from the first extension portion CKL1_1. For example, the first protrusion portion CKL1_2 may protrude in a direction opposite to the first direction DR1 from the first extension portion CKL1_1.

For example, the second clock line CKL2 may overlap the second gate emission signal generator 320 in a plan view. The second clock line CKL2 may be connected to the second connection pattern CP2 through a contact hole. The second clock line CKL2 may output the second clock signal CLK2 to the second connection pattern CP2.

In an embodiment, the first gate emission signal generator 310 and the second gate emission signal generator 320 may be connected to the same second clock line CKL2. For example, the second clock line CKL2 may be connected to the first gate pattern GP1 through the second connection pattern CP2. Accordingly, the second clock signal CLK2 may be applied to the upper gate electrode of the first transistor T1 of the first gate emission signal generator 310 and the upper gate electrode of the first transistor T1 of the second gate emission signal generator 320 through the second clock line CKL2 and the second connection pattern CP2.

In an embodiment, the second clock line CKL2 may include a second extension portion CKL2_1 extending in the second direction DR2 and a second protrusion portion CKL2_2 protruding from the second extension portion CKL2_1. For example, the second protrusion portion CKL2_2 may protrude in the first direction DR1 from the second extension portion CKL2_1.

The second low voltage line VLL2 may be connected to the first connection pattern CP1, the sixth connection pattern CP6, the seventh connection pattern CP7, and the eleventh connection pattern CP11 through contact holes. The second low voltage line VLL2 may output the second low gate voltage VGL2 to the first connection pattern CP1, the sixth connection pattern CP6, the seventh connection pattern CP7, and the eleventh connection pattern CP11.

The high voltage line VHL may be connected to the ninth connection pattern CP9 through a contact hole. The high voltage line VHL may output the high gate voltage VGH to the ninth connection pattern CP9. In FIGS. 18 and 19, the high voltage line VHL not connected to other patterns may output the high gate voltage VGH to stages other than the second stage STG2.

As described above, FIGS. 7 to 21 are layout views illustrating the second stage (e.g., the second stage STG2 of FIG. 4) as an example of a stage included in the gate emission driver (e.g., the gate emission driver 300 of FIG. 4), and thus in FIGS. 18 and 19, the initiation signal line FLL may not be connected to other patterns.

The second via insulating layer VIA2 may be disposed on the sixth conductive layer CL6, and may cover the first low voltage line VLL1, the first clock line CKL1, the second clock line CKL2, the second low voltage line VLL2, the high voltage line VHL, and the initiation signal line FLL. For example, the second via insulating layer VIA2 may include an organic insulating material.

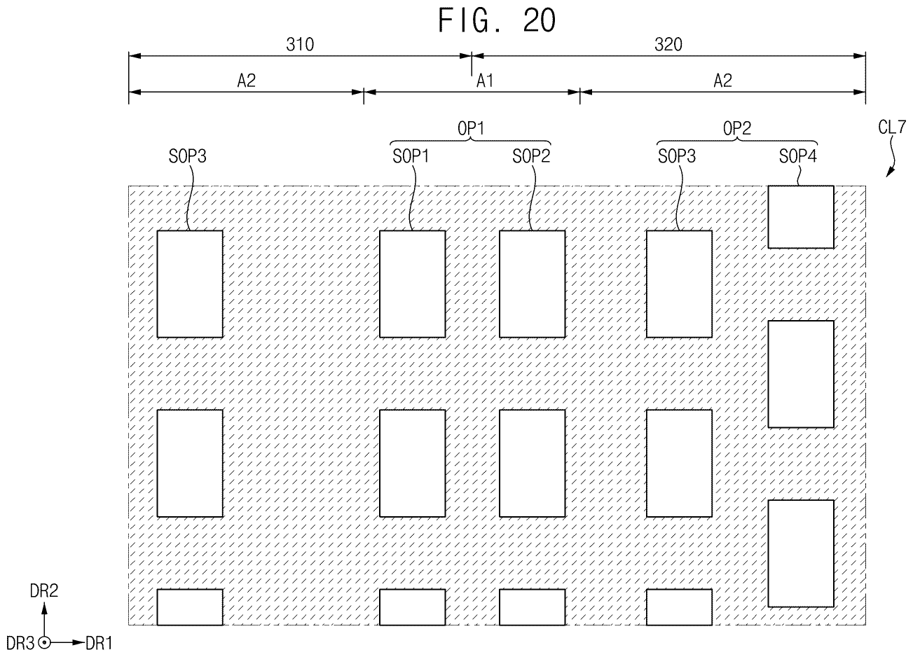

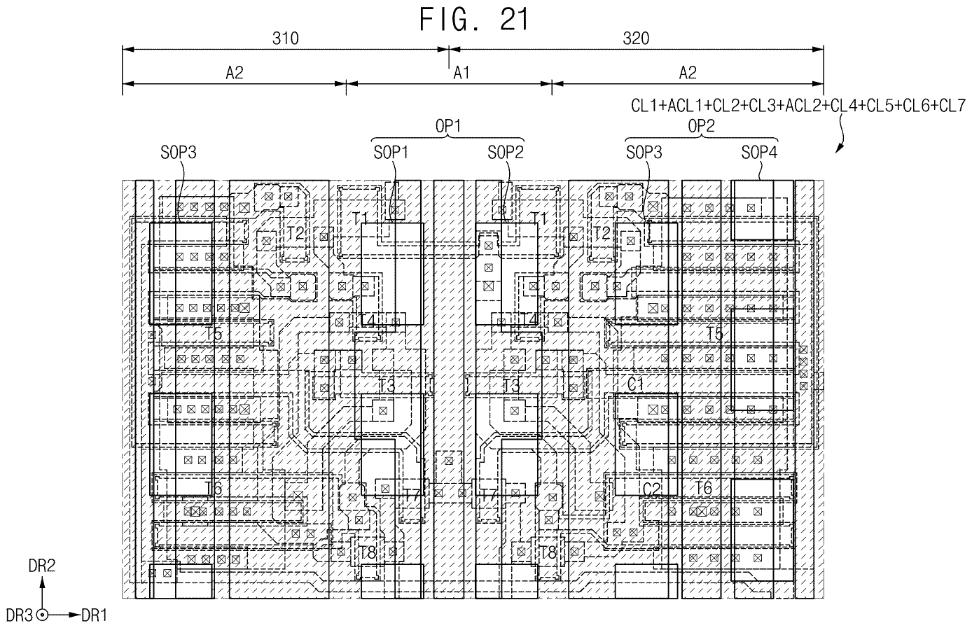

FIG. 20 is a layout view illustrating a seventh conductive layer CL7. FIG. 21 is a layout view in which the seventh conductive layer CL7 is further disposed on the sixth conductive layer CL6 of FIG. 19. FIG. 22 is a layout view in which the seventh conductive layer CL7 is disposed on the sixth conductive layer CL6.

Referring further to FIGS. 20, 21, and 22, the seventh conductive layer CL7 may be disposed on the sixth conductive layer CL6. For example, the seventh conductive layer CL7 may be disposed on the second via insulating layer VIA2.

The seventh conductive layer CL7 may include a conductive material such as a metal, an alloy, a conductive metal nitride, a conductive metal oxide, a transparent conductive oxide, or the like. The seventh conductive layer CL7 may be disposed in the same layer as the pixel electrode PE of FIG. 3. For example, the seventh conductive layer CL7 may be electrically connected to the common electrode CME of FIG. 3, and may stably supply a voltage to the common electrode CME to reduce a voltage drop of the common electrode CME. The seventh conductive layer CL7 may be disposed in the non-display area NDA to surround the display area DA. The seventh conductive layer CL7 may be disposed on the gate emission driver 300 of FIG. 4. The seventh conductive layer CL7 may overlap the first gate emission signal generator 310 and the second gate emission signal generator 320 in a plan view.

In an embodiment, the seventh conductive layer CL7 may define openings penetrating the seventh conductive layer CL7 in a thickness direction (i.e., the third direction DR3). The seventh conductive layer CL7 may define first openings OP1 and second openings OP2. The first openings OP1 may be spaced apart from the second openings OP2. A planar shape of the first opening OP1 may be different from a planar shape of the second opening OP2.

The seventh conductive layer CL7 may include a first area A1 in which the first openings OP1 are defined and a second area A2 in which the second openings OP2 are defined. In an embodiment, the first area A1 may be an area overlapping the first and second clock lines CKL1 and CKL2 in a plan view, and the second area A2 may be an area other than the first area. The first openings OP1 may overlap the first and second clock lines CKL1 and CKL2 in a plan view, and the second openings OP2 may not overlap the first and second clock lines CKL1 and CKL2 in a plan view. The seventh conductive layer CL7 may expose at least a portion of the second via insulating layer VIA2 of FIG. 3 through the first and second openings OP1 and OP2.

The first and second openings OP1 and OP2 may provide paths through which materials included in an insulating layer disposed below the seventh conductive layer CL7 are vaporized and discharged to the outside. When a thermal process (e.g., a curing process) is performed after the pixel define layer PDL is formed on the pixel electrode PE, a portion of the material included in the first insulating layer VIA1 or the second via insulating layer VIA2 below the seventh conductive layer CL7 may be vaporized by heat applied during the thermal process and be discharged to the outside through the first and second openings OP1 and OP2. Accordingly, damage to the light emitting element LD of FIG. 3 caused by gas generated from the first and second via insulating layers VIA1 and VIA2 may be prevented.

When the seventh conductive layer CL7 overlaps the first and second clock lines CKL1 and CKL2 in a plan view, the voltage supplied to the seventh conductive layer CL7 may be affected by parasitic capacitance formed between the first and second clock lines CKL1 and CKL2 and the seventh conductive layer CL7. In an embodiment, in order to minimize the influence of the parasitic capacitance on the voltage supplied to the seventh conductive layer CL7, the first openings OP1 may overlap the first and second clock lines CKL1 and CKL2 in a plan view. As the parasitic capacitance is reduced, power consumption may be reduced.

In an embodiment, each of the first openings OP1 may include a first sub-opening SOP1 overlapping at least a portion of the first clock line CKL1 in a plan view and a second sub-opening SOP2 overlapping at least a portion of the second clock line CKL2 in a plan view.

The first sub-openings SOP1 may be spaced apart from each other along the second direction DR2, and the second sub-openings SOP2 may be spaced apart from each other along the second direction DR2. The second sub-openings SOP2 may be spaced apart from the first sub-openings SOP1 in the first direction DR1. In an embodiment, the first sub-openings SOP1 and the second sub-openings SOP2 may be symmetrical with respect to a virtual line extending in the second direction DR2. For example, the first sub-openings SOP1 and the second sub-openings SOP2 may be line-symmetrical with respect to the first low voltage line VLL1.

In an embodiment, each of the first sub-openings SOP1 may overlap the first extension portion CKL1_1 of the first clock line CKL1 in a plan view, and each of the second sub-openings SOP2 may overlap the second extension portion CKL2_1 of the second clock line CKL2 in a plan view. For example, in a plan view, each of the first sub-openings SOP1 may entirely overlap the first extension portion CKL1_1, and may partially overlap the first protrusion portion CKL1_2. For example, in a plan view, each of the second sub-openings SOP2 may entirely overlap the second extension portion CKL2_1, and may partially overlap the second protrusion portion CKL2_2.

As the parasitic capacitance formed between the first clock line CKL1 and the seventh conductive layer CL7 increases, an output of a signal transmitted through the first clock line CKL1 may be delayed, and as the parasitic capacitance formed between the second clock line CKL2 and the seventh conductive layer CL7 increases, an output of a signal transmitted through the second clock line CKL2 may be delayed. Since the first and second sub-openings SOP1 and SOP2 are symmetrically formed, an area of the first clock line CKL1 overlapping the first sub-openings SOP1 in a plan view and an area of the second clock line CKL2 overlapping the second sub-openings SOP2 in a plan view may be substantially the same (or equal). Accordingly, a deviation between the parasitic capacitance formed between the first clock line CKL1 and the seventh conductive layer CL7 and the parasitic capacitance formed between the second clock line CKL2 and the seventh conductive layer CL7 may be minimized. That is, a deviation between the output of the signal transmitted through the first clock line CKL1 and the output of the signal transmitted through the second clock line CKL2 may be minimized.

In an embodiment, each of the second openings OP2 may include a third sub-opening SOP3 and a fourth sub-opening SOP4 arranged in an offset (or zigzag) manner along the second direction DR2. The third sub-openings SOP3 may be spaced apart from each other in the first direction DR1 and the second direction DR2, and the fourth sub-openings SOP4 may be spaced apart from each other in the first direction DR1 and the second direction DR2. The fourth sub-opening SOP4 may be spaced apart from the third sub-opening SOP3 in the first direction DR1 and staggered with respect to the third sub-openings SOP3 in the second direction DR2. The third sub-openings SOP3 and the fourth sub-openings SOP4 may be alternately arranged along the first direction DR1, with their centers offset in the second direction DR2.

The second openings OP2 may control a flow of the encapsulation layer TFE of FIG. 3. When the organic encapsulation layer of the encapsulation layer TFE of FIG. 3 is formed, the third sub-openings SOP3 and the fourth sub-openings SOP4 arranged in an offset (or staggered) manner may impede a flow of organic material included in the organic encapsulation layer, and thus a profile (e.g., a position of an end) of the organic encapsulation layer may be controlled.

Although the first, second, third, and fourth sub-openings SOP1, SOP2, SOP3, and SOP4 are illustrated as having a rectangular planar shape in the drawing, the present disclosure is not limited thereto. For example, the first, second, third, and fourth sub-openings SOP1, SOP2, SOP3, and SOP4 may have various shapes such as a polygonal planar shape, a circular planar shape, an elliptical planar shape, or the like. In addition, sizes of the first and second sub-openings SOP1 and SOP2 and sizes of the third and fourth sub-openings SOP3 and SOP4 may be the same or different.

The display device DD according to an embodiment of the present disclosure may include the seventh conductive layer CL7 defining the first opening OP1 including the first sub-opening SOP1 overlapping the first clock line CKL1 in a plan view and the second sub-opening SOP2 overlapping the second clock line CKL2 in a plan view. Accordingly, parasitic capacitance formed between the first and second clock lines CKL1 and CKL2 and the seventh conductive layer CL7 may be reduced, and power consumption of the display device DD may be reduced. In addition, the first sub-opening SOP1 and the second sub-opening SOP2 may be symmetrical with respect to a virtual line extending in the second direction DR2, and an area of the first clock line CKL1 overlapping the first sub-opening SOP1 in a plan view and an area of the second clock line CKL2 overlapping the second sub-opening SOP2 in a plan view may be substantially the same. Accordingly, a deviation between parasitic capacitance formed between the first clock line CKL1 and the seventh conductive layer CL7 and parasitic capacitance formed between the second clock line CKL2 and the seventh conductive layer CL7 may be minimized, and a deviation between an output of a signal transmitted through the first clock line CKL1 and an output of a signal transmitted through the second clock line CKL2 may be minimized.

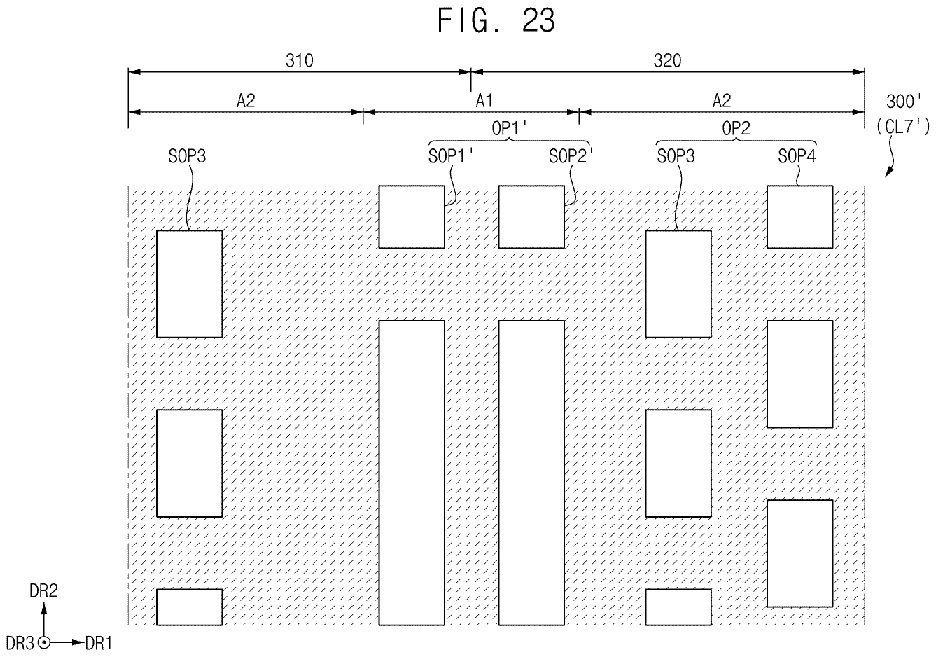

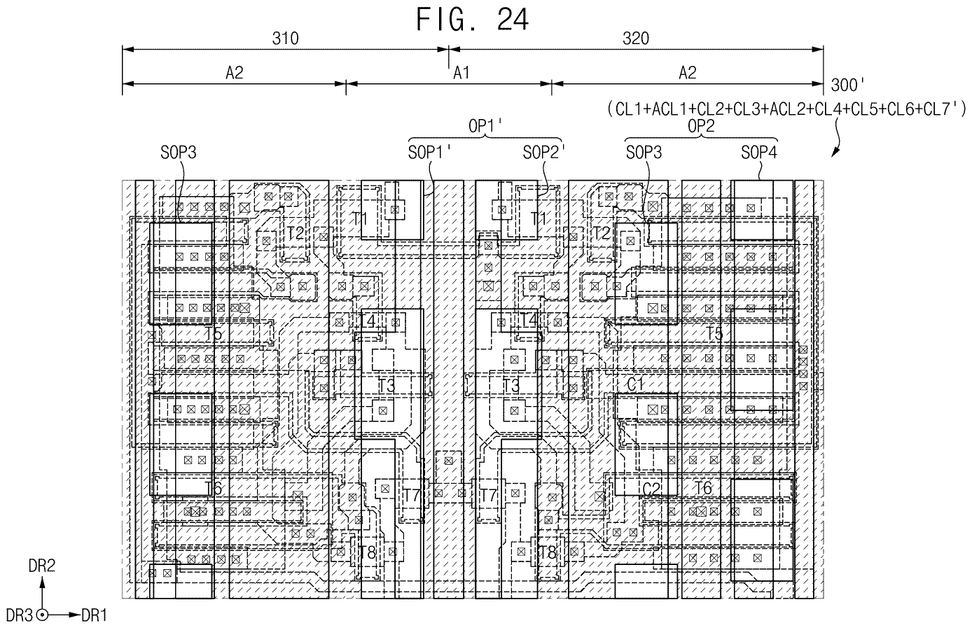

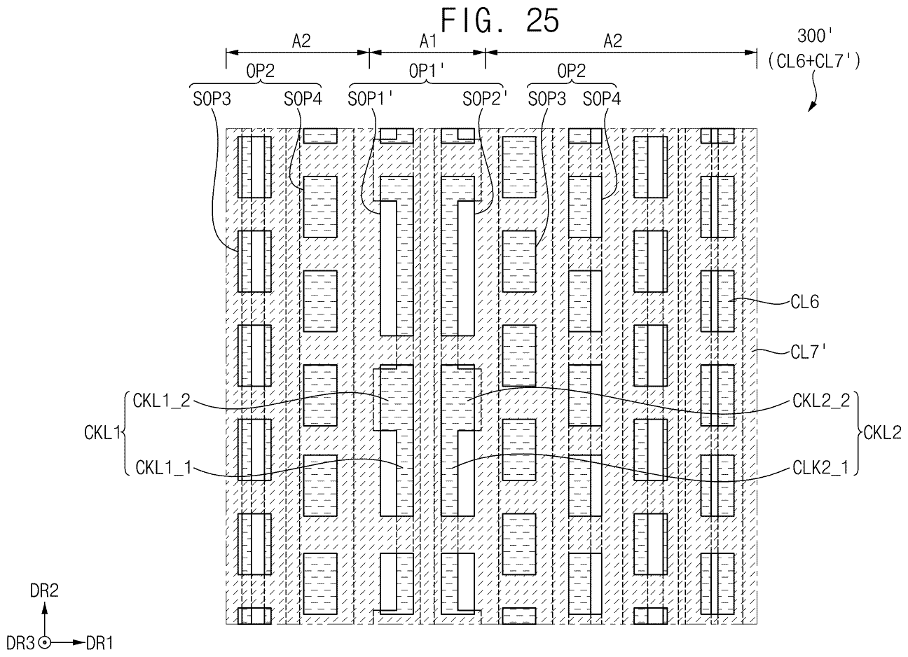

FIGS. 23, 24, and 25 are layout views illustrating a stage included in a gate emission driver according to an embodiment of the present disclosure. FIGS. 23 and 24 may be layout views illustrating a stage included in a gate emission driver 300′. FIG. 25 may be a layout view illustrating a portion of a plurality of stages included in the gate emission driver 300′.

The gate emission driver 300′ described with reference to FIGS. 23, 24, and 25 may be substantially the same as or similar to the gate emission driver 300 described with reference to FIGS. 2 to 22, except for a seventh conductive layer CL7′. For example, the gate emission driver 300′ described with reference to FIGS. 23, 24, and 25 may be included in a display device (e.g., the display device DD of FIG. 1). Hereinafter, redundant descriptions will be omitted or simplified.

FIG. 23 is a layout view illustrating a seventh conductive layer CL7′. FIGS. 24 and 25 are layout views in which the seventh conductive layer CL7′ is further disposed on the sixth conductive layer CL6. FIG. 23 may correspond to FIG. 20, FIG. 24 may correspond to FIG. 21, and FIG. 25 may correspond to FIG. 22.

Referring to FIGS. 23, 24, and 25, each stage included in the gate emission driver 300′ may include a first gate emission signal generator 310 and a second gate emission signal generator 320 that are substantially symmetrical with respect to a virtual line extending in the second direction DR2.

The seventh conductive layer CL7′ may be disposed on the sixth conductive layer CL6. The seventh conductive layer CL7′ may be disposed in the same layer as a pixel electrode (e.g., the pixel electrode PE of FIG. 3), and may overlap the first and second gate emission signal generators 310 and 320 in a plan view.

The seventh conductive layer CL7′ may define first openings OP1′ and second openings OP2 penetrating the seventh conductive layer CL7′ in a thickness direction (i.e., the third direction DR3). The seventh conductive layer CL7′ may include a first area A1 defined as an area in which the first openings OP1′ are defined and a second area A2 defined as an area in which the second openings OP2 are defined. The first openings OP1′ may overlap the first and second clock lines CKL1 and CKL2 in the first area A1 in a plan view, and the second openings OP2 may not overlap the first and second clock lines CKL1 and CKL2 in the second area A2 in a plan view.

Each of the first openings OP1′ may include a first sub-opening SOP1′ overlapping at least a portion of the first clock line CKL1 in a plan view and a second sub-opening SOP2′ overlapping at least a portion of the second clock line CKL2 in a plan view. In an embodiment, the first sub-openings SOP1′ and the second sub-openings SOP2′ may be symmetrical with respect to a virtual line extending in the second direction DR2.

Since the first and second sub-openings SOP1′ and SOP2′ are symmetrically formed, an area of the first clock line CKL1 overlapping the first sub-openings SOP1′ in a plan view and an area of the second clock line CKL2 overlapping the second sub-openings SOP2′ in a plan view may be substantially the same. Accordingly, a deviation between parasitic capacitance formed between the first clock line CKL1 and the seventh conductive layer CL7′ and parasitic capacitance formed between the second clock line CKL2 and the seventh conductive layer CL7′ may be minimized.

Lengths of each of the first sub-openings SOP1′ in the second direction DR2 may be the same or different. Likewise, lengths of each of the second sub-openings SOP2′ in the second direction DR2 may be the same or different.

Each of the second openings OP2 may include a third sub-opening SOP3 and a fourth sub-opening SOP4 that are arranged in an offset (or zigzag) manner.

Planar shapes of the first and second sub-openings SOP1′ and SOP2′ may be the same as or different from planar shapes of the third and fourth sub-openings SOP3 and SOP4. For example, a length of at least one of the first sub-openings SOP1′ in the second direction DR2 and a length of at least one of the second sub-openings SOP2′ in the second direction DR2 may be greater than a length of either the third or the fourth sub-openings SOP3 and SOP4 in the second direction DR2.

The gate emission driver 300′ according to an embodiment of the present disclosure may include the seventh conductive layer CL7′ defining the first opening OP1′ including the first sub-opening SOP1′ overlapping the first clock line CKL1 in a plan view and the second sub-opening SOP2′ overlapping the second clock line CKL2 in a plan view. Accordingly, parasitic capacitance formed between the first and second clock lines CKL1 and CKL2 and the seventh conductive layer CL7′ may be reduced, and power consumption of the display device may be reduced. In addition, the first sub-opening SOP1′ and the second sub-opening SOP2′ may be symmetrical with respect to a virtual line extending in the second direction DR2, and an area of the first clock line CKL1 overlapping the first sub-opening SOP1′ in a plan view and an area of the second clock line CKL2 overlapping the second sub-opening SOP2′ in a plan view may be substantially the same. Accordingly, a deviation between parasitic capacitance formed between the first clock line CKL1 and the seventh conductive layer CL7′ and parasitic capacitance formed between the second clock line CKL2 and the seventh conductive layer CL7′ may be minimized, and a deviation between an output of a signal transmitted through the first clock line CKL1 and an output of a signal transmitted through the second clock line CKL2 may be minimized.

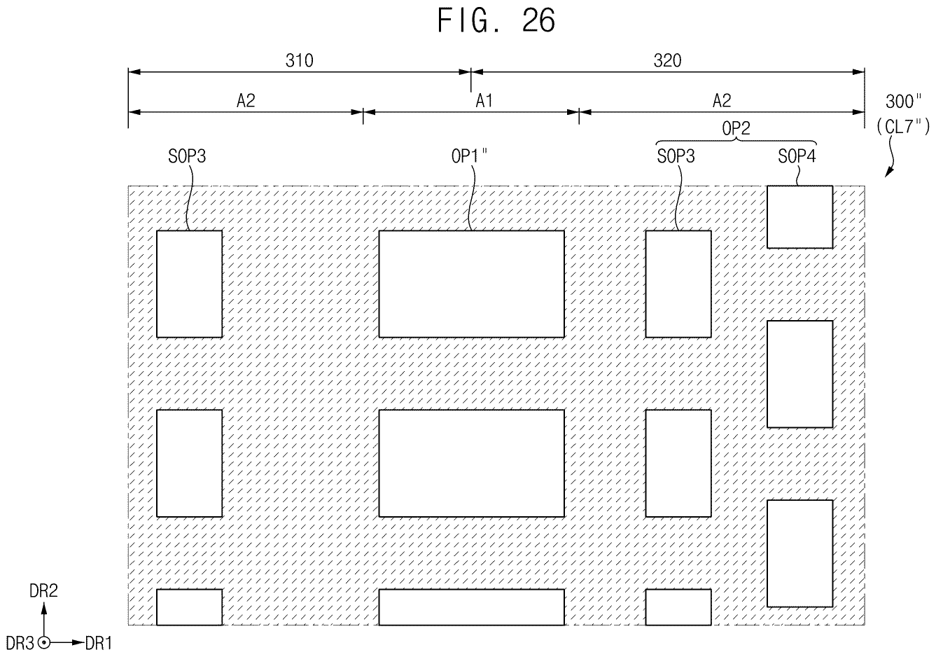

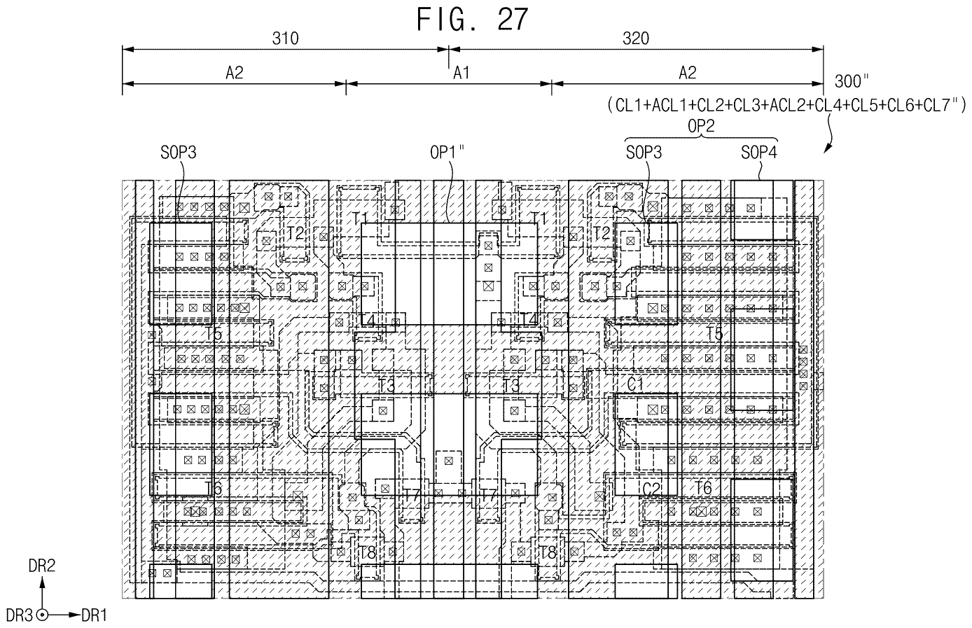

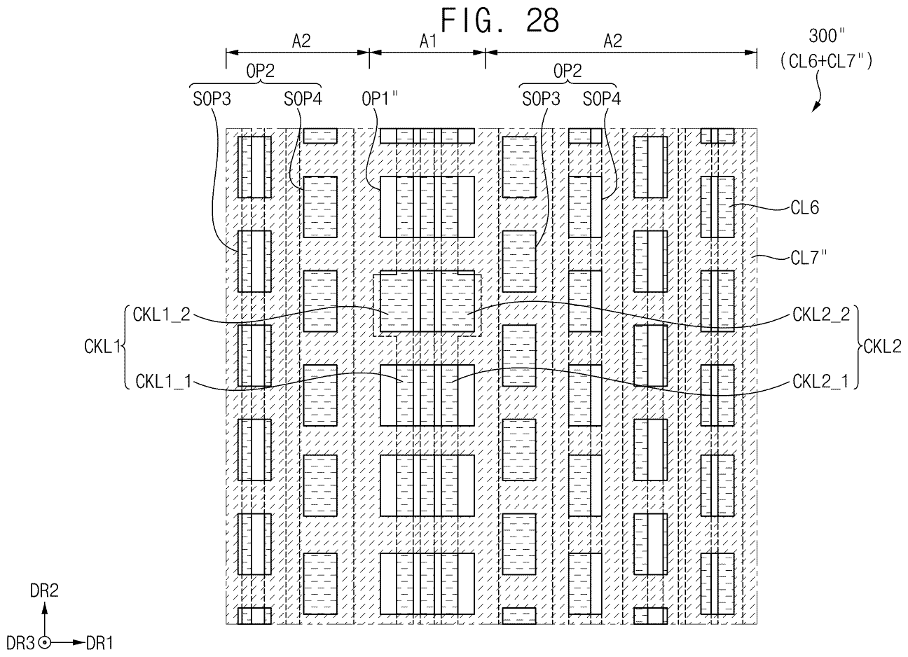

FIGS. 26, 27, and 28 are layout views illustrating a stage included in a gate emission driver according to an embodiment of the present disclosure. FIGS. 26 and 27 may be layout views illustrating a stage included in a gate emission driver 300″. FIG. 28 may be a layout view illustrating a portion of a plurality of stages included in the gate emission driver 300″.

The gate emission driver 300″ described with reference to FIGS. 26, 27, and 28 may be substantially the same as or similar to the gate emission driver 300 described with reference to FIGS. 2 to 22, except for a seventh conductive layer CL7″. For example, the gate emission driver 300″ described with reference to FIGS. 26, 17, and 28 may be included in a display device (e.g., the display device DD of FIG. 1). Hereinafter, redundant descriptions will be omitted or simplified.

FIG. 26 is a layout view illustrating a seventh conductive layer CL7″. FIGS. 27 and 28 are layout views in which the seventh conductive layer CL7″ is further disposed on the sixth conductive layer CL6. FIG. 26 may correspond to FIG. 20, FIG. 27 may correspond to FIG. 21, and FIG. 28 may correspond to FIG. 22.

Referring to FIGS. 26, 27, and 28, each stage included in the gate emission driver 300″ may include a first gate emission signal generator 310 and a second gate emission signal generator 320 that are substantially symmetrical with respect to a virtual line extending in the second direction DR2.

The seventh conductive layer CL7″ may be disposed on the sixth conductive layer CL6. The seventh conductive layer CL7″ may be disposed in the same layer as a pixel electrode (e.g., the pixel electrode PE of FIG. 3), and may overlap the first and second gate emission signal generators 310 and 320 in a plan view.

The seventh conductive layer CL7″ may define first openings OP1″ and second openings OP2 penetrating the seventh conductive layer CL7″ in a thickness direction (i.e., the third direction DR3). The seventh conductive layer CL7″ may include a first area A1 defined as an area in which the first openings OP1″ are defined and a second area A2 defined as an area in which the second openings OP2 are defined. The first openings OP1″ may overlap the first and second clock lines CKL1 and CKL2 in the first area A1 in a plan view, and the second openings OP2 may not overlap the first and second clock lines CKL1 and CKL2 in the second area A2 in a plan view.

Each of the first openings OP1″ may overlap at least a portion of the first and second clock lines CKL1 and CKL2 in a plan view. An area of the first clock line CKL1 overlapping the first openings OP1″ in a plan view and an area of the second clock line CKL2 overlapping the first openings OP1″ in a plan view may be substantially the same. Accordingly, a deviation between parasitic capacitance formed between the first clock line CKL1 and the seventh conductive layer CL7″ and parasitic capacitance formed between the second clock line CKL2 and the seventh conductive layer CL7″ may be minimized. Lengths of each of the first openings OP1″ in the second direction DR2 may be the same or different.

Each of the second openings OP2 may include a third sub-opening SOP3 and a fourth sub-opening SOP4 that are arranged in an offset (or zigzag) manner.

Planar shapes of the first openings OP1″ may be the same as or different from planar shapes of the third and fourth sub-openings SOP3 and SOP4. For example, a length of at least one of the first openings OP1″ in the first direction DR1 may be longer than a length of the third and fourth sub-openings SOP3 and SOP4 in the first direction DR1.

The gate emission driver 300″ according to an embodiment of the present disclosure may include the seventh conductive layer CL7″ defining the first opening OP1″ overlapping the first clock line CKL1 and the second clock line CKL2 in a plan view. Accordingly, parasitic capacitance formed between the first and second clock lines CKL1 and CKL2 and the seventh conductive layer CL7″ may be reduced, and power consumption of the display device may be reduced. In addition, an area of the first clock line CKL1 overlapping the first opening OP1″ in a plan view and an area of the second clock line CKL2 overlapping the first opening OP1″ in a plan view may be substantially the same. Accordingly, a deviation between parasitic capacitance formed between the first clock line CKL1 and the seventh conductive layer CL7″ and parasitic capacitance formed between the second clock line CKL2 and the seventh conductive layer CL7″ may be minimized, and a deviation between an output of a signal transmitted through the first clock line CKL1 and an output of a signal transmitted through the second clock line CKL2 may be minimized.

The gate emission driver 300, 300′, and 300″ and the display device DD including the gate emission driver according to embodiments of the present disclosure may be applied to various electronic devices. An electronic device according to an embodiment of the present disclosure may include the display device including the gate emission driver described above, and may further include a module or device having other additional functions in addition to the display device.

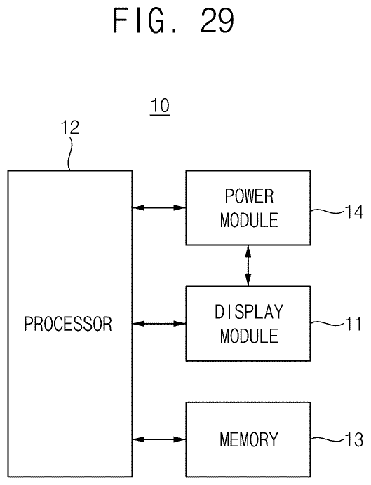

FIG. 29 is a block diagram illustrating an electronic device according to an embodiment of the present disclosure.

Referring to FIG. 29, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), and an image signal processor (ISP).

The memory 13 may store data information necessary for operation of the processor 12 or the display module 11. When the processor 12 executes an application stored in the memory 13, an input image data signal and/or a control signal may be transmitted to the display module 11, and the display module 11 may process the received signal and output image information through a display screen.

The power module 14 may include a power supply module, such as a power adapter or a battery device, and a power conversion module that converts power supplied by the power supply module to generate power required for operation of the electronic device 10.

At least one of components of the electronic device 10 may be included in the display device according to embodiments of the present disclosure described above. In addition, some of individual modules functionally included in one module may be included in the display device, and other portions may be provided separately from the display device. For example, the display device may include the display module 11, and the processor 12, the memory 13, and the power module 14 may be provided in form of other devices within the electronic device 10 other than the display device.

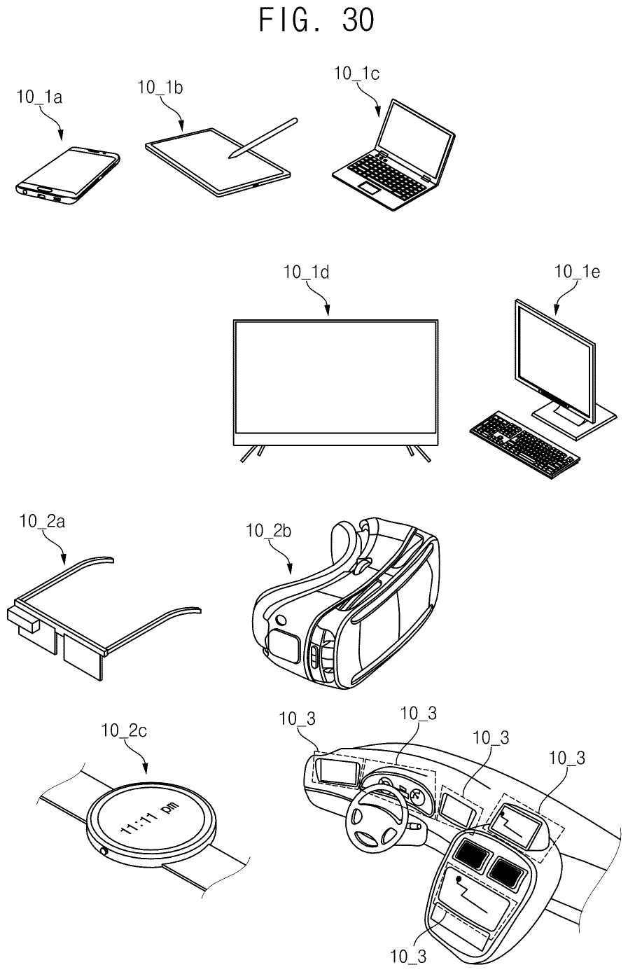

FIG. 30 is a schematic view illustrating electronic devices according to embodiments of the present disclosure.

Referring to FIG. 30, various electronic devices to which the display device according to an embodiment of the present disclosure is applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a Center Information Display (CID) arranged on a cluster, a center fascia, and dashboard of a car, and a room mirror display, or the like.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting of the disclosure. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a display panel including a light emitting element;
a driver including a first gate emission signal generator that generates a first driving signal and a second gate emission signal generator that generates a second driving signal different from the first driving signal;
a first conductive layer including a clock line electrically connected to each of the first gate emission signal generator and the second gate emission signal generator; and
a second conductive layer disposed on the first conductive layer and defining a first opening overlapping at least a portion of the clock line in plan view and a second opening spaced apart from the first opening.

2. The display device of claim 1, wherein:
the second gate emission signal generator is adjacent to the first gate emission signal generator in a first direction, and
the first gate emission signal generator and the second gate emission signal generator are symmetrical with respect to a first virtual line extending in a second direction intersecting the first direction.

3. The display device of claim 2, wherein:
the driver includes a plurality of stages arranged in rows,
each of the plurality of stages includes the first gate emission signal generator and the second gate emission signal generator, and
the clock line includes:
a first clock line connected to stages located in odd-numbered rows among the plurality of stages; and
a second clock line connected to stages located in even-numbered rows among the plurality of stages.

4. The display device of claim 3, wherein the first opening includes:
a first sub-opening overlapping the first clock line in plan view; and
a second sub-opening overlapping the second clock line in plan view.

5. The display device of claim 4, wherein the first sub-opening and the second sub-opening are symmetrical with respect to a second virtual line extending in the second direction.

6. The display device of claim 4, wherein an area in which the first sub-opening and the first clock line overlap in plan view is equal to an area in which the second sub-opening and the second clock line overlap in plan view.

7. The display device of claim 4, wherein:
the first clock line includes:
a first extension portion extending in the second direction; and
a first protrusion portion protruding from the first extension portion, and
the first sub-opening overlaps the first extension portion in plan view.

8. The display device of claim 4, wherein:
the second clock line includes:
a second extension portion extending in the second direction; and
a second protrusion portion protruding from the second extension portion, and
the second sub-opening overlaps the second extension portion in plan view.

9. The display device of claim 4, wherein the second opening includes:
a third sub-opening; and
a fourth sub-opening spaced apart from the third sub-opening in the first direction and staggered with respect to the third sub-opening in the second direction.

10. The display device of claim 9, wherein a planar shape of each of the first sub-opening and the second sub-opening is different from a planar shape of each of the third sub-opening and the fourth sub-opening.

11. The display device of claim 3, wherein the first opening overlaps the first clock line and the second clock line in plan view.

12. The display device of claim 3, wherein the first conductive layer further includes a low voltage line disposed between the first clock line and the second clock line.

13. The display device of claim 1, wherein the second conductive layer overlaps the first gate emission signal generator and the second gate emission signal generator in plan view.

14. The display device of claim 1, wherein:
the second conductive layer includes:
a first area overlapping the clock line in plan view; and
a second area not overlapping the clock line in plan view,
the first opening is defined in the first area, and
the second opening is defined in the second area.

15. The display device of claim 1, wherein:
the light emitting element includes a pixel electrode, a common electrode, and a light emitting layer between the pixel electrode and the common electrode, and
the second conductive layer is electrically connected to the common electrode.

16. An electronic device comprising:
a display device; and
a processor that provides input image data and an input signal to the display device,
wherein the display device includes:
a display panel including a light emitting element;
a driver including a first gate emission signal generator that generates a first driving signal and a second gate emission signal generator that generates a second driving signal different from the first driving signal;
a first conductive layer including a clock line electrically connected to each of the first gate emission signal generator and the second gate emission signal generator; and
a second conductive layer disposed on the first conductive layer and defining a first opening overlapping at least a portion of the clock line in plan view and a second opening spaced apart from the first opening.

17. The electronic device of claim 16, wherein:
the second gate emission signal generator is adjacent to the first gate emission signal generator in a first direction, and
the first gate emission signal generator and the second gate emission signal generator are symmetrical with respect to a virtual line extending in a second direction intersecting the first direction.

18. The electronic device of claim 17, wherein
the clock line includes:
a first clock line; and
a second clock line spaced apart from the first clock line in the first direction, and
the first opening includes:
a first sub-opening overlapping the first clock line in plan view; and
a second sub-opening overlapping the second clock line in plan view.

19. The electronic device of claim 18, wherein the first sub-opening and the second sub-opening are symmetrical with respect to a virtual line extending in the second direction.

20. The electronic device of claim 18, wherein an area in which the first sub-opening and the first clock line overlap in plan view is equal to an area in which the second sub-opening and the second clock line overlap in plan view.
